(19) United States
(12) Patent Application Publication
(10) Pub. No.: US 2023/0204669 A1
(43) Pub. Date: Jun. 29, 2023

(54) INFORMATION PROCESSING APPARATUS, INFORMATION PROCESSING METHOD, COMPUTER PROGRAM PRODUCT, AND MOVING OBJECT

(71) Applicants: KABUSHIKI KAISHA TOSHIBA, Tokyo (JP); Toshiba Infrastructure Systems & Solutions Corporation, Kawasaki-shi Kanagawa (JP)

(72) Inventors: Arika FUKUSHIMA, Kawasaki Kanagawa (JP); Katsuyoshi SUZUKI, Soka Saitama (JP)

(73) Assignees: KABUSHIKI KAISHA TOSHIBA, Tokyo (JP); TOSHIBA INFRASTRUCTURE SYSTEMS & SOLUTIONS CORPORATION, Kawasaki-shi Kanagawa (JP)

(21) Appl. No.: 18/177,548

(22) Filed: Mar. 2, 2023

Related U.S. Application Data
(63) Continuation of application No. PCT/JP2022/003146, filed on Jan. 27, 2022.

(30) Foreign Application Priority Data
Sep. 1, 2021 (JP) 2021-142645

(51) Int. Cl. G01R 31/367; G01R 31/387

(52) U.S. Cl. CPC G01R 31/367; G01R 31/387

(57) ABSTRACT

According to an embodiment, an information processing apparatus includes one or more hardware processors configured to calculate a prediction value of an amount of electric power consumed for a movement to be predicted, based on a prediction model in which the amount of electric power consumed by a moving object is an objective variable, one or more factor values that affect the amount of electric power consumed for the movement of the moving object to be predicted, and an error between the prediction value obtained by the prediction model and an actual measured value.

### CROSS-REFERENCE TO RELATED APPLICATIONS

This application is a continuation application of International Application No. PCT/JP2022/003146, filed on Jan. 27, 2022, which is based upon and claims the benefit of priority from Japanese Patent Application No. 2021-142645, filed on Sep. 1, 2021; the entire contents of which are incorporated herein by reference.

### FIELD

Embodiments described herein relate generally to an information processing apparatus, an information processing method, a computer program product, and a moving object.

### BACKGROUND

For example, in order to prevent an electric vehicle from running out of charge during traveling, a prediction value of the amount of electric power consumed while the vehicle travels is calculated in advance, and it is demanded to charge the vehicle with the amount of electric power equal to or greater than the prediction value before traveling. The prediction value of the amount of the consumed electric power of an electric vehicle is calculated by a mathematical model employing observation values, which are obtained from observation on a traveling distance, a speed, and a temperature, and used as input variables. However, there are factors that are not included in the input variables and factors that are difficult to quantify such as the driver's driving skill, and it was difficult to reflect these factors in the mathematical model. Therefore, in situations where factors that are difficult to be reflect in the mathematical model have a significant impact on the amount of the consumed electric power, the prediction values are less likely to be accurately calculated using a mathematical model in the related art.

### BRIEF DESCRIPTION OF THE DRAWINGS

FIG. 1 is a diagram illustrating a configuration of a prediction device according to a first embodiment with a moving object;

FIG. 2 is a diagram illustrating an example of a movement table according to the first embodiment;

FIG. 3 is a diagram illustrating an example of a movement unit for creating movement data;

FIG. 4 is a diagram illustrating an example of a prediction model;

FIG. 5 is a diagram illustrating an example of an error table;

FIG. 6 is a flowchart illustrating a flow of creation processing of movement data;

FIG. 7 is a flowchart illustrating a flow of creation processing of evaluation data;

FIG. 8 is a diagram illustrating an example of the evaluation data;

FIG. 9 is a flowchart illustrating a flow of creation processing of result data;

FIG. 10 is a diagram illustrating an example of the result data;

FIG. 11 is a flowchart illustrating a flow of calculation processing of a prediction value;

FIG. 12 is a diagram illustrating a configuration of a prediction device according to a second embodiment with a moving object;

FIG. 13 is a flowchart illustrating a flow of processing executed by the prediction device according to the second embodiment;

FIG. 14 is a diagram illustrating a configuration of a prediction device according to a third embodiment with a moving object;

FIG. 15 is a diagram illustrating an example of a movement table according to the third embodiment;

FIG. 16 is a flowchart illustrating a flow of update processing of errors in an operator table;

FIG. 17 is a diagram illustrating an example of the operator table;

FIG. 18 is a diagram illustrating a configuration of a prediction device according to a fourth embodiment with a moving object;

FIG. 19 is a diagram illustrating a configuration of a prediction device according to a fifth embodiment with a moving object;

FIG. 20 is a diagram illustrating a configuration of a prediction device according to a sixth embodiment with a moving object;

FIG. 21 is a diagram illustrating a configuration of a prediction device according to a seventh embodiment with a moving object;

FIG. 22 is a diagram illustrating an example of an approximate curve;

FIG. 23 is a flowchart illustrating a flow of update processing of category values;

FIG. 24 is a diagram illustrating an example of a configuration file;

FIG. 25 is a diagram illustrating an example of threshold values;

FIG. 26 is a diagram illustrating a first example of calculation processing of the category values;

FIG. 27 is a diagram illustrating a second example of the calculation processing of the category values;

FIG. 28 is a diagram illustrating a correspondence relationship between the category values and model input values;

FIG. 29 is a diagram illustrating an example of an output image; and

FIG. 30 is a diagram illustrating an example of a hardware configuration of the prediction device.

### DETAILED DESCRIPTION

According to an embodiment, an information processing apparatus includes one or more hardware processors configured to calculate a prediction value of an amount of electric power consumed for a movement to be predicted, based on a prediction model in which the amount of electric power consumed by a moving object is an objective variable, one or more factor values that affect the amount of electric power consumed for the movement of the moving object to be predicted, and an error between the prediction value obtained by the prediction model and an actual measured value.

Exemplary embodiments of an information processing apparatus, an information processing method, a computer program product, and a moving object will be explained below in detail with reference to the accompanying drawings. The present invention is not limited to the following embodiments. Hereinbelow, a prediction device 20 according to a plurality of embodiments will be described with reference to the drawings.

### First Embodiment

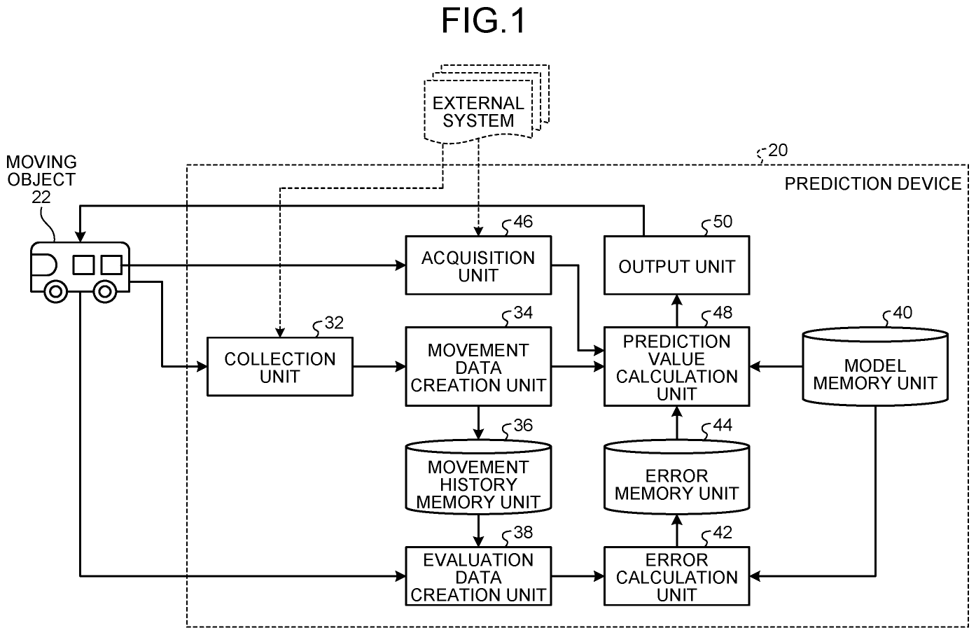

FIG. 1 is a diagram illustrating a configuration of the prediction device 20 according to a first embodiment with a moving object 22.

The prediction device 20 predicts the amount of electric power consumed by the moving object 22. The moving object 22 is provided with a secondary battery and are moved by electric power stored in the secondary battery. In the present embodiment, the moving object 22 is a route bus that repeatedly travels one and the same route. The moving object 22 may be, for example, an electric vehicle, a train traveling on a track, or other types of vehicles instead of the route bus. The moving object 22 may be a marine vessel, an airplane, a drone, or the like. The moving object 22 may be a vehicle or the like that does not repeatedly travels one and the same route.

The prediction device 20 is implemented by an information processing apparatus such as a computer. The prediction device 20 may be an information processing apparatus that operates independently, or may be a device that includes one or more information processing apparatuses linked to each other, and that is implemented by a server, cloud or the like, such as a network. The prediction device 20 may be mounted in the moving object 22 or in a charging system that charges the moving object 22 with electric power.

The prediction device 20 calculates a prediction value of the amount of electric power consumed by movement of such a moving object 22. The prediction device 20 then outputs the prediction value obtained by the calculation to, for example, an operator or the like of the moving object 22.

The prediction device 20 is provided with a collection unit 32, a movement data creation unit 34, a movement history memory unit 36, an evaluation data creation unit 38, a model memory unit 40, an error calculation unit 42, an error memory unit 44, an acquisition unit 46, a prediction value calculation unit 48, and an output unit 50.

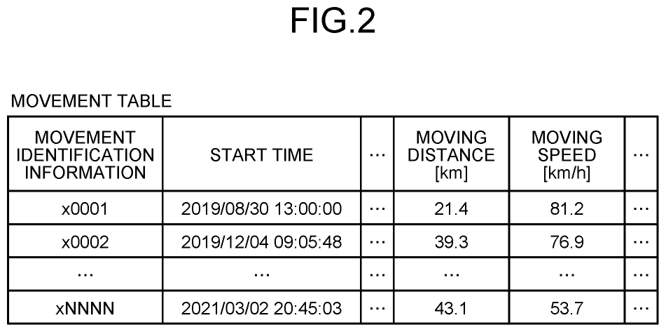

The collection unit 32 acquires one or more factor values representing one or more factors that affect the amount of electric power consumed for movement of the moving object 22, in a case where the moving object 22 moves by one unit. Further details on one or more factor values are described later with reference to FIG. 2.

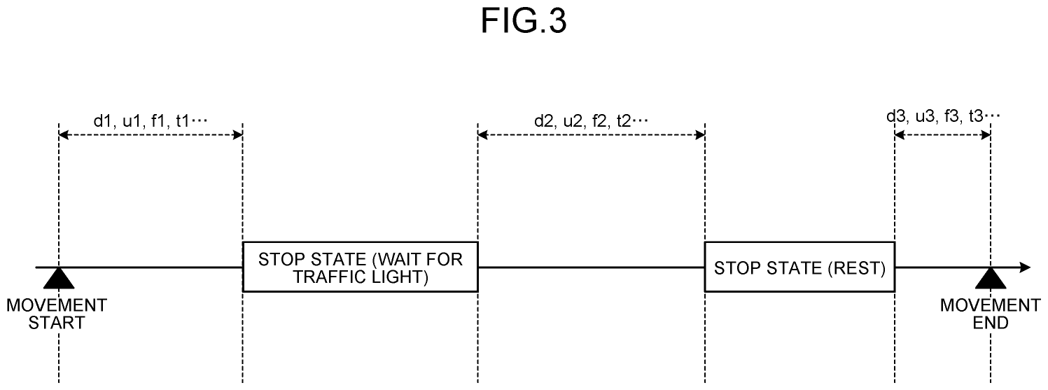

Movement of the moving object 22 by one unit is, for example, a movement unit from which actual measured values of the amount of electric power consumed by the moving object 22 can be obtained. Further details on the movement of the moving object 22 by one unit are described later with reference to FIG. 3.

The collection unit 32 may acquire some or all of the one or more factor values from an external system that is implemented by a server or the like, via a network. The collection unit 32 may also acquire some or all of the one or more factor values from a measuring instrument, a terminal device, or a memory device provided in the moving object 22. The collection unit 32 transmits the collected one or more factor values to the movement data creation unit 34.

The movement data creation unit 34 generates movement identification information for identifying movement by one unit for each case where the moving object 22 moves by one unit. The movement data creation unit 34 creates one piece of movement data including the generated movement identification information and the one or more factor values acquired from the collection unit 32. The movement data creation unit 34 stores the created movement data in a movement table stored in the movement history memory unit 36.

The movement history memory unit 36 stores the movement table capable of storing a plurality of pieces of the movement data. The movement table stores one piece of movement data in one record. The movement history memory unit 36 creates a new record in the movement table for each case where the movement data creation unit 34 acquires movement data, and stores the movement data in the created new record.

In a case where the movement of the moving object 22 by one unit ends, the evaluation data creation unit 38 acquires an actual measured value of the amount of electric power actually consumed by the moving object 22, which is due to the corresponding movement by one unit. The evaluation data creation unit 38 acquires, for example, the actual measured value from the moving object 22. In the case where the movement of the moving object 22 by one unit ends, the evaluation data creation unit 38 creates evaluation data that includes the actual measured values acquired and the movement data for the corresponding movement by one unit. The evaluation data creation unit 38 then transmits the created evaluation data to the error calculation unit 42.

The model memory unit 40 stores a prediction model in which one or more factor values are used as an input variable group and the amount of consumed electric power is an objective variable. In the present embodiment, the model memory unit 40 stores a first prediction model and a second prediction model. The first prediction model is a model for predicting the amount of consumed electric power by using the one or more factor values without using an error between the prediction value and the actual measured value. The second prediction model is a model for predicting the amount of consumed electric power by using the one or more factor values with the error between the prediction value and the actual measured value.

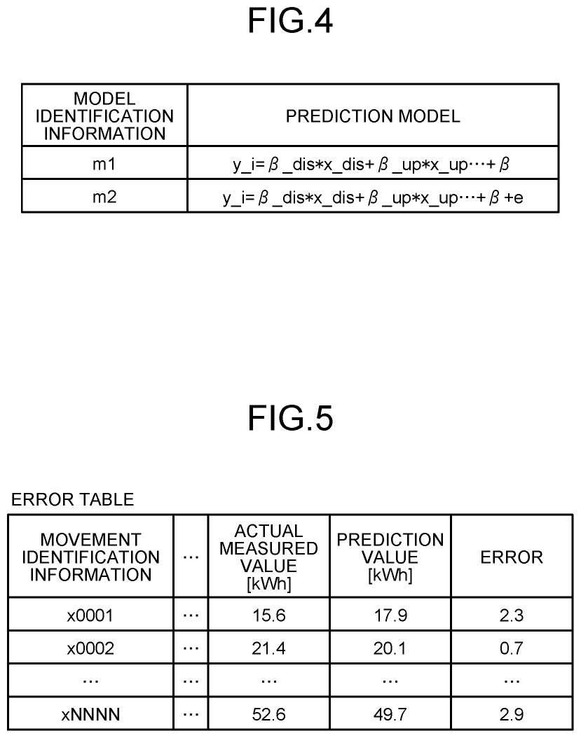

The first prediction model and the second prediction model are pre-trained. In the present embodiment, the second prediction model is a model that yields the same result as the first prediction model, provided that the error is set to zero. For example, the second prediction model is a model for calculating a prediction value by addition of an error to a value predicted by using the first prediction model. Further details on the prediction model are described later with reference to FIG. 4.

In the case where the movement of the moving object 22 by one unit ends, the error calculation unit 42 acquires the evaluation data for the corresponding movement by one unit from the evaluation data creation unit 38. The error calculation unit 42 acquires the first prediction model from the model memory unit 40. Furthermore, the error calculation unit 42 extracts the one or more factor values included in the moving data section of the acquired evaluation data. Then, the error calculation unit 42 calculates a prediction value of the amount of electric power consumed in the past for movement by one unit where the movement has ended by using the one or more factor values extracted from the evaluation data and the first prediction model.

Furthermore, the error calculation unit 42 calculates an error between the calculated prediction value of the amount of electric power consumed in the past and the actual measured value included in the evaluation data for the corresponding movement by one unit. The error calculation unit 42 creates one piece of result data including the calculated error and the evaluation data acquired from the evaluation data creation unit 38. The error calculation unit 42 stores the created result data in an error table stored in the error memory unit 44.

The error memory unit 44 stores the error table capable of storing a plurality of pieces of the result data. The error table stores one piece of error data in one record. The error memory unit 44 creates a new record in the error table for each case where the error calculation unit 42 acquires result data, and stores the result data in the created new record.

In a case of predicting the amount of electric power consumed for movement of the moving object 22 to be predicted, the acquisition unit 46 acquires one or more factor values representing one or more factors affecting the amount of electric power consumed for movement of the moving object 22 to be predicted. Items of the one or more factor values acquired by the acquisition unit 46 are the same as items of the one or more factor values collected by the collection unit 32. The prediction device 20 may be implemented by a common module of the collection unit 32 and the acquisition unit 46.

The acquisition unit 46 receives, for example, a prediction instruction input from an operator or the like, and acquires one or more factor values, in a case where the prediction instruction is received. In a case where the moving object 22 starts to move, the acquisition unit 46 may acquire one or more factor values prior to the start of the movement, regarding the movement as movement to be predicted. In this case, the one or more factor values that are collected by the collection unit 32 in order to create the movement data are identical to the one or more factor values acquired by the acquisition unit 46 with respect to the movement to be predicted. The acquisition unit 46 transmits the acquired one or more factor values with respect to the movement to be predicted to the prediction value calculation unit 48.

The prediction value calculation unit 48 receives the one or more factor values from the acquisition unit 46 and acquires the prediction model from the model memory unit 40. The prediction value calculation unit 48 calculates a prediction value of the amount of electric power consumed for the movement to be predicted by using a prediction model in which the one or more factor values are used as an input variable group and the amount of consumed electric power is an objective variable, based on one or more factor values acquired by the acquisition unit 46.

Here, the prediction value calculation unit 48 calculates the prediction value with respect to movement to be predicted, by using an error between a prediction value of the amount of electric power consumed in the past, which is obtained via the prediction model with respect to the movement of the moving object 22 in the past, and an actual measured value of the amount of electric power consumed for the movement in the past, and the prediction model. In the present embodiment, the prediction value calculation unit 48 calculates a prediction value with respect to movement to be predicted by using the second prediction model stored in the model memory unit 40, in a case where there is an error with respect to movement in the past in the error table in the error memory unit 44, that is, a case where at least one piece of the result data is stored in the error table. The prediction value calculation unit 48 also calculates a prediction value with respect to movement to be predicted by using the first prediction model stored in the model memory unit 40, in a case where there is no error with respect to the movement in the past in the error table in the error memory unit 44, that is, a case where no result data is stored in the error table.

The prediction value calculation unit 48 selects any one of errors and calculates a prediction value with respect to movement to be predicted by using the selected error and the prediction model, in a case where there are errors with respect to the movement in the past in the error table in the error memory unit 44, that is, a case where the pieces of the result data is stored in the error table. In the present embodiment, the prediction value calculation unit 48 calculates a prediction value with respect to the movement to be predicted, by using an error for the latest movement of the movement to be predicted out of a plurality of the movements of the moving object 22 in the past and the prediction model. Here, the latest movement is movement in the past that is performed in the nearest time with respect to the movement to be predicted. The prediction value calculation unit 48 can calculate a prediction value with favorable accuracy by using an error for movement that is performed in the nearest time to the movement to be predicted.

In a case where the prediction value calculation unit 48 has calculated a prediction value, the output unit 50 outputs the calculated prediction value. The output unit 50 may display the prediction value on a display device in the moving object 22, for example, or on a display device provided in a charging system that charges the moving object 22 with electric power, for example.

FIG. 2 is a diagram illustrating an example of a movement table according to the first embodiment.

The movement table can store a plurality of pieces of movement data. The movement data includes unique movement identification information. For example, the movement identification information is generated by incrementing a value by one in time series.

As an example, the one or more factor values include any one or more of a start position, an end position, a moving distance, a cumulative value of an uphill gradient, a cumulative value of a downhill gradient, a start time, an end time, a moving time, a speed, a weight, an internal temperature, and an external temperature.

The start position is a position where movement of the moving object 22 by one unit starts, and is represented by, for example, latitude, longitude, and the like. The end position is a position where movement of the moving object 22 by one unit ends, and is represented by, for example, latitude, longitude, and the like. The moving distance represents a distance of a route over which the moving object 22 will travel.

The cumulative value of the uphill gradient is a total uphill gradient which is totaled from the start position to the end position in the route. A map server or the like provides elevation values on the route at equal intervals, for example, about one meter or the like. For example, the collection unit 32 collects an elevation value group on the route from the map server or the like and calculates the cumulative value of the uphill gradient. For example, the collection unit 32 calculates the cumulative value of the uphill gradient by adding up all of sets of values that are positive numbers, and differences from the next point's elevation value in an elevation value in a moving direction of the route.

The cumulative value of the downhill gradient is a total downhill gradient which is totaled from the start position to the end position in the route. For example, the collection unit 32 collects an elevation value group on the route from the map server or the like and calculates the cumulative value of the downhill gradient. For example, the collection unit 32 calculates the cumulative value of the downhill gradient by adding up all of sets of absolute values that are negative numbers, which are differences from the next point's elevation value in an elevation value in the moving direction of the route.

The start time is a time where movement of the moving object 22 by one unit starts, and is represented by, for example, the form “Year/Month/Date and Time:Minute:Second” and the like. The end time is a time where movement of the moving object 22 by one unit ends, and is represented by, for example, the form “Year/Month/Date and Time:Minute:Second” and the like. The moving time is a time when the moving object 22 has substantially moved, and for example, a time excluding a stop time such as waiting for traffic light or rest from the start time to the end time.

The speed is a speed of the moving object 22. The speed may be an average of speeds during the movement, excluding the stop time such as waiting for traffic light or rest.

The weight is a weight of the moving object 22. For example, in a case where the weight varies during the movement, the weight may be an average value of weights at regular intervals during the movement.

The internal temperature is a temperature inside the moving object 22. In a case where the internal temperature varies during the movement, the internal temperature may be, for example, an average value of internal temperatures at regular intervals during the movement.

The external temperature is an ambient temperature of the moving object 22. In a case where the external temperature varies during the movement, the external temperature may be, for example, an average value of external temperatures at regular intervals during the movement.

The one or more factor values are not limited to only such information. The one or more factor values may include other information such as, for example, the acceleration of the moving object 22, a motor temperature, and an air conditioner temperature.

FIG. 3 is a diagram illustrating an example of a movement unit for creating movement data.

A movement unit for creating movement data is, for example, a continuous section where the speed of the moving object 22 is not zero. As illustrated in FIG. 3, the movement unit for creating movement data may be, for example, a section that integrates a plurality of sections excluding stop sections in a case where the moving object 22 waits for traffic light during the movement and stops for a rest or other reasons. Thus, in a case where the movement unit is the section that integrates the sections excluding stop sections, the moving distance, the cumulative value of the uphill gradient, cumulative value of the downhill gradient, and the moving time are represented as follows.

For example, in a case where the sets of the distances for the sections excluding waiting for traffic light, rest, and the like are denoted by d1, d2, . . . , dM, a moving distance (x_dis) for movement by one unit is represented as follows.

x_dis=d1+d2+ . . . +dM

For example, in a case where the sets of the cumulative values of an uphill gradient for the sections excluding waiting for traffic light, rest, and the like are denoted by u1, u2, . . . , uM, a cumulative value of the uphill gradient (x_up) for movement by one unit is represented as follows.

x_up=u1+u2+ . . . +uM

For example, in a case where the sets of the cumulative values of a downhill gradient for the sections excluding waiting for traffic light, rest, and the like are denoted by f1, f2, . . . , fM, a cumulative value of the downhill gradient (x_fall) for movement by one unit is represented as follows.

x_fall=f1+f2+ . . . +fM

For example, in a case where the sets of the moving times for the sections excluding waiting for traffic light, rest, and the like are denoted by t1, t2, . . . , tM, a moving time (x_time) for movement by one unit is represented as follows.

x_time=t1+T2+ . . . +tM

FIG. 4 is a diagram illustrating an example of the prediction model. In the present embodiment, the model memory unit 40 stores the first prediction model and the second prediction model. For example, the model memory unit 40 stores the first prediction model and the second prediction model corresponding to the model identification information (m1 and m2).

In the present embodiment, the first prediction model is represented as in the following Equation.

y_i=f(x_dis,x_up,x_fall, . . . ) m1:

f( ) is a function representing the prediction model. f( ) can be any model as long as it has a general form of model, such as a multiple regression model, a neural network, a deep learning, a physical model, or other forms of model.

In the present embodiment, the second prediction model is represented as in the following Equation.

y_i=f(x_dis,x_up,x_fall, . . . )+e m2:

e represents an error. A value stored in the error table in the error memory unit 44 is used as the error. That is, the second prediction model is represented in the form of an error added to a value predicted by the first prediction model.

As illustrated in FIG. 4, the first prediction model and the second prediction model may be multiple regression models. In this case, f( ) is represented by {β_is, β_up, . . . , β_intercept}. Regression coefficients {β_dis, β_up, . . . , β_intercept} are estimated based on the pieces of result data stored in the error table in the error memory unit 44, by using a factor group affecting the amount of electric power consumed and an actual measured value of the amount of electric power consumed. A parameter tuning method for estimating regression coefficients may be a general method, such as a least squares method, for example.

FIG. 5 is a diagram illustrating an example of the error table. The error table stores an actual measured value and a prediction value of the amount of consumed electric power, and an error by associating each of one or more movements in the past with the movement identification information in addition to the same item as the movement table.

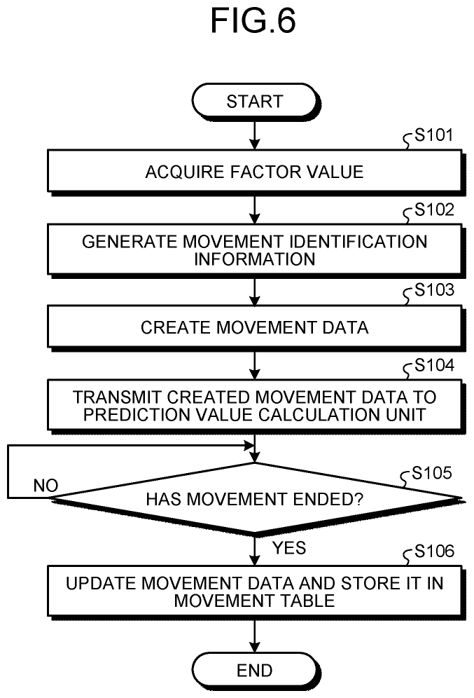

FIG. 6 is a flowchart illustrating a flow of creation processing of the movement data executed by the prediction device 20. In a case where the moving object 22 moves, the prediction device 20 executes the creation processing of the movement data according to the flow illustrated in FIG. 6.

First, at S101, the collection unit 32 collects one or more factor values representing one or more factors affecting the amount of electric power consumed for the movement of the moving object 22. For example, the collection unit 32 acquires, from the moving object 22, a start position, an end position, an end time, a moving time, a speed, a weight, and an internal temperature as part of one or more factor values. The collection unit 32 may employ estimation values or expected values instead of uncertain information at the time when the movement starts, for example, the end time, the moving time, the speed, and the weight.

Furthermore, the collection unit 32 acquires, based on the start position, the end position, and the route, a moving distance, a cumulative values of an uphill gradient, and a cumulative value of a downhill gradient from a map server or the like that is, for example, an external system via a network, for example. Furthermore, the collection unit 32 acquires, based on the start position, the end position, and the route, an external temperature from a weather server or the like that is, for example, an external system. For example, the collection unit 32 acquires the external temperature at a position through which it is predicted that the moving object 22 passes from a weather server or the like at regular intervals from the start time to the end time. For example, the collection unit 32 may acquire the current external temperature from a thermometer provided in the moving object 22 instead of acquiring the external temperature from the weather server. In a case where the collection unit 32 acquires the external temperature from the weather server, the internal temperature may be corrected according to the obtained external temperature.

Next, at S102, the movement data creation unit 34 generates movement identification information. The movement data creation unit 34 may generate movement identification information by incrementing movement identification information on, for example, the previous movement. Next, at S103, the movement data creation unit 34 creates movement data that includes the generated movement identification information and the collected one or more factor values.

Next, at S104, the movement data creation unit 34 transmits the generated movement data to the prediction value calculation unit 48, in a case where a prediction value is calculated by employing the current movement of the moving object 22 as movement to be predicted. In this case, the prediction value calculation unit 48 calculates the prediction value of the amount of electric power consumed for the current movement of the moving object based on the movement data acquired from the movement data creation unit 34.

Next, at S105, the movement data creation unit 34 determines whether the movement of the moving object 22 has ended. In a case where the movement is proceeding (No at S105), the movement data creation unit 34 causes the processing at S105 to be put on standby. In a case where the movement has ended (No at S105), the movement data creation unit 34 allows the processing to proceed to S106.

At S106, the movement data creation unit 34 updates a factor value for a factor that can be replaced by an actual measured value out of one or more factor values included in the movement data. The movement data creation unit 34 may update the moving time to an actual moving time, which excludes, for example, a stop time for the purpose of waiting for traffic light and rest. The movement data creation unit 34 may also update the end time to a time when the movement has been actually ended. For example, the movement data creation unit 34 may also update the speed, the weight, the internal temperature, and the external temperature to actually measured values. In this case, in a case where measured values of the speed, the weight, the internal temperature, and the external temperature are sampled and acquired at regular intervals during a period when the moving object 22 is moving, the movement data creation unit 34 may employ average values or the like obtained by averaging the measured values individually. The movement data creation unit 34 may not update any value of the one or more factor values included in the movement data to an actual measured value.

The movement data creation unit 34 stores the movement data in the movement table stored in the movement history memory unit 36. In a case where the processing at S106 ends, the prediction device 20 ends the flow. Executing the processing described above by the prediction device 20 enables movement data to be generated for each time when the moving object 22 moves by one unit, and enables the generated movement data to be stored in the movement table.

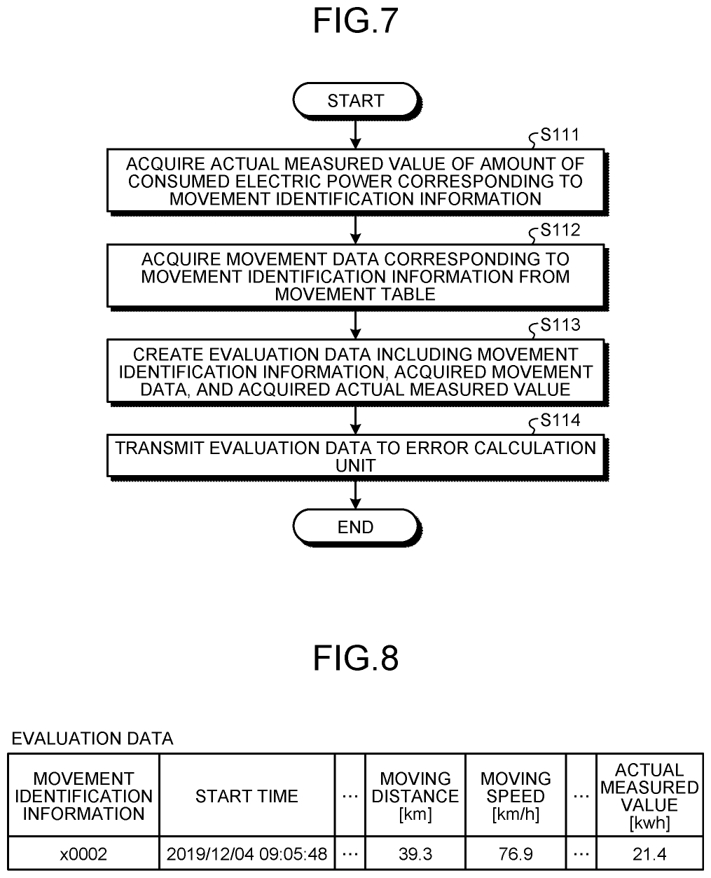

FIG. 7 is a flowchart illustrating a flow of creation processing of evaluation data executed by the prediction device 20. FIG. 8 is a diagram illustrating an example of the evaluation data created by the processing illustrated in FIG. 7. After the movement of the moving object 22 has been ended, and the movement data has been stored in the movement table, the prediction device 20 executes the creation processing of the evaluation data according to the flow illustrated in FIG. 7.

First, at S111, the evaluation data creation unit 38 acquires, from the moving object 22, an actual measured value of the amount of electric power actually consumed for the movement corresponding to the movement identification information included in the movement data created by the movement data creation unit 34.

Next, at S112, the evaluation data creation unit 38 acquires the movement data stored in the movement table stored in the movement history memory unit 36 for the movement corresponding to the movement identification information included in the movement data created by the movement data creation unit 34.

Next, at S113, the evaluation data creation unit 38 creates evaluation data including the movement identification information, the acquired movement data, and the acquired actual measured value of the amount of electric power.

Next, at S114, the evaluation data creation unit 38 transmits the created evaluation data to the error calculation unit 42. For example, the evaluation data creation unit 38 creates evaluation data as illustrated in FIG. 8 and transmits the created evaluation data to the error calculation unit 42.

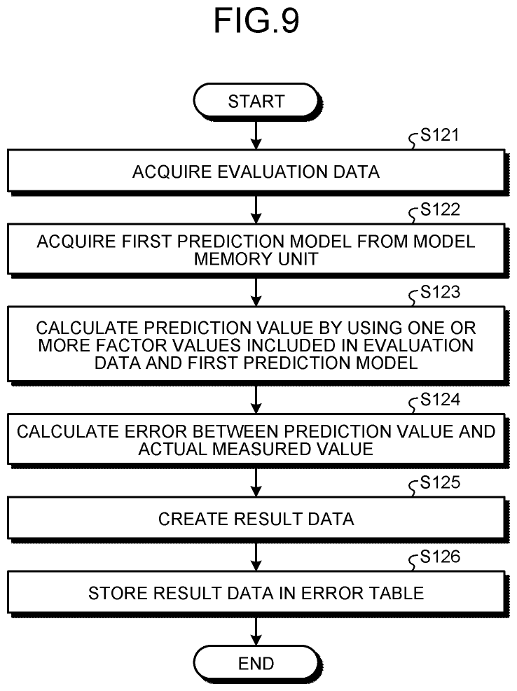

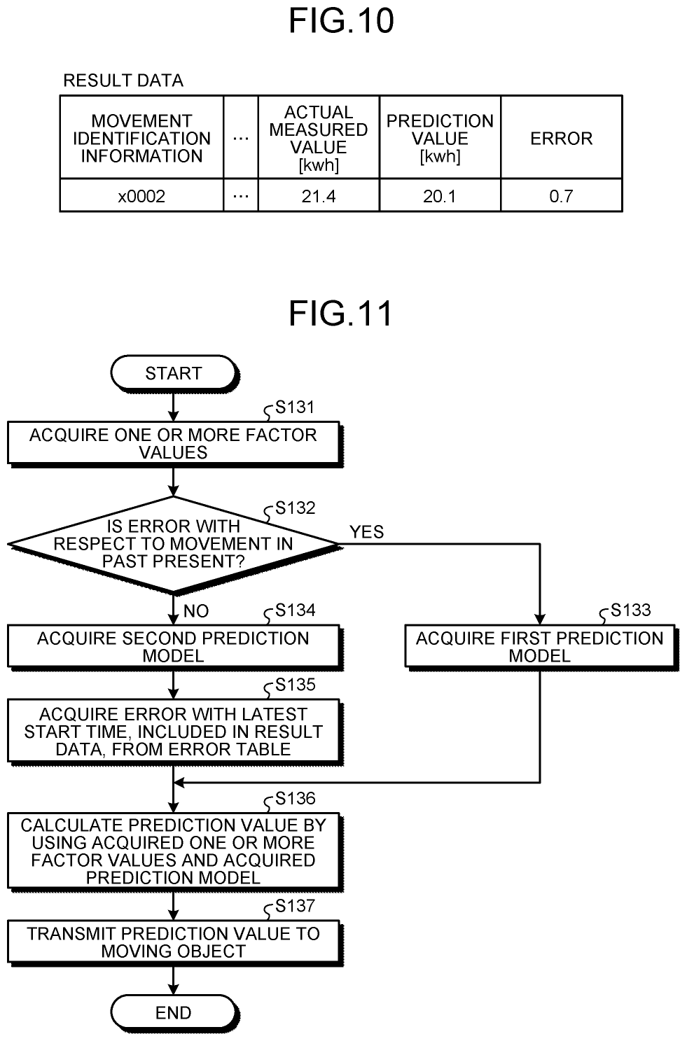

FIG. 9 is a flowchart illustrating a flow of creation processing of result data executed by the prediction device 20. FIG. 10 is a diagram illustrating an example of the result data created by the processing illustrated in FIG. 9. After the evaluation data has been created, the prediction device 20 executes the creation processing of the result data according to the flow illustrated in FIG. 9.

First, at S121, in a case where the movement of the moving object 22 by one unit ends, the error calculation unit 42 acquires the evaluation data for the corresponding movement by one unit from the evaluation data creation unit 38.

Next, at S122, the error calculation unit 42 acquires the first prediction model from the model memory unit 40. That is, the error calculation unit 42 acquires a prediction model for predicting the amount of consumed electric power by using the one or more factor values without using an error between the prediction value and the actual measured value.

Next, at S123, the error calculation unit 42 extracts the one or more factor values included in the movement data section in the acquired evaluation data, and calculates prediction values for the movement in the past by using the one or more factor values extracted from the evaluation data and the first prediction model.

Next, at S124, the error calculation unit 42 calculates errors between the calculated prediction value and the actual measured value contained in the acquired evaluation data.

For example, the error calculation unit 42 calculates the errors by the following operation. In Expressions described below, e_i represents an error. y\hat{ }_i represents the prediction value. y_i represents the actual measured value.

e_i=y\hat{ }_i−y_i Difference:

e_i=|y\hat{ }i−y_i| Absolute error:

e_i=(y\hat{ }_i−y_i)\hat{ }2 Squared error:

e_i=(y\hat{ }_i−y_i)/y_i Relative error:

/y_i|y\hat{ }i−y_i|y_i Absolute error ratio:

e_i=(y\hat{ }_i−y_i)\hat{ }2/y_i Squared error ratio:

The error calculation unit 42 may calculate errors by using other general error calculation operation expressions without limitation to the above Expressions.

Next, at S125, the error calculation unit 42 creates one piece of result data including the calculated error and the evaluation data acquired from the evaluation data creation unit 38.

Next, at S126, the error calculation unit 42 stores the created result data in the error table stored in the error memory unit 44. For example, the error calculation unit 42 creates the result data illustrated in FIG. 10 and stores the created result data in the error table. In a case where the processing at S126 ends, the prediction device 20 ends the flow. Executing the processing described above by the prediction device 20 enables result data to be generated for each time when the moving object 22 moves by one unit, and enables the generated result data to be stored in the error table.

FIG. 11 is a flowchart illustrating a flow of calculation processing of a prediction value obtained by the prediction device 20. In a case of predicting the amount of electric power consumed for the movement of the moving object 22 to be predicted, the prediction device 20 executes the calculation processing of the prediction value according to the flow illustrated in FIG. 11.

First, at S131, the prediction value calculation unit 48 acquires one or more factor values representing one or more factors affecting the amount of electric power consumed for the movement to be predicted. For example, in a case where the movement data is created by the movement data creation unit 34 prior to the movement of the moving object 22, the prediction value calculation unit 48 acquires one or more factor values included in the movement data. Alternatively, the prediction value calculation unit 48 acquires one or more factor values from the acquisition unit 46, in a case where the acquisition unit 46 receives a prediction instruction input from an operator or the like, regardless of the movement of the moving object 22.

Next, at S132, the prediction value calculation unit 48 determines whether an error with respect to movement in the past is present in the error table stored in the error memory unit 44. That is, the prediction value calculation unit 48 determines whether the error table contains at least one piece of the result data. In a case where there is no error with respect to movement in the past in the error table, the prediction value calculation unit 48 allows the processing to proceed to S133. In a case where there is at least one error with respect to the movement in the past in the error table, the prediction value calculation unit 48 allows the processing to proceed to S134.

At S133, the prediction value calculation unit 48 acquires the first prediction model from the model memory unit 40. That is, the prediction value calculation unit 48 acquires the prediction model for predicting the amount of consumed electric power by using the one or more factor values without using an error between the prediction value and the actual measured value. In a case where the prediction value calculation unit 48 ends the processing at S133, the prediction value calculation unit 48 allows the processing to proceed to S136.

At S134, the prediction value calculation unit 48 acquires the second prediction model from the model memory unit 40. That is, the prediction value calculation unit 48 acquires the prediction model for predicting the amount of consumed electric power by using the one or more factor values based on the error between the prediction value and the actual measured value. In a case where the prediction value calculation unit 48 ends the processing at S134, the prediction value calculation unit 48 allows the processing to proceed to S135.

At S135, the prediction value calculation unit 48 acquires an error with respect to movement in the past from the error table stored in the error memory unit 44. In the present embodiment, the prediction value calculation unit 48 acquires an error for the latest movement of the movement to be predicted out of the movements of the moving object 22 in the past. In a case where the prediction value calculation unit 48 ends the processing at S135, the prediction value calculation unit 48 allows the processing to proceed to S136.

At S136, the prediction value calculation unit 48 calculates a prediction value of the amount of electric power consumed for the movement of the moving object 22 to be predicted based on the acquired one or more factor values and the acquired prediction model. More specifically, in a case where there is no error for movement in the past, the prediction value calculation unit 48 calculates the prediction value by using the acquired one or more factor values and the first prediction model. In a case where there is an error for the movement in the past, the prediction value calculation unit 48 calculates the prediction value by using the acquired error, the acquired one or more factor values, and the second prediction model.

Next, at S137, the output unit 50 outputs the prediction value calculated by the prediction value calculation unit 48. For example, the output unit 50 transmits the prediction value to the moving object 22. In this case, the output unit 50 may also transmit the movement identification information included in the corresponding movement data along with the prediction value. The output unit 50 may output the prediction value to other devices. For example, the output unit 50 may output the calculated prediction value to a charging system that charges the moving object 22 with electric power.

As described above, the prediction device 20 according to the first embodiment calculates the prediction value of the amount of electric power consumed for the movement of the moving object 22 to be predicted by using the error between the prediction value and actual measured value of the amount of electric power consumed by the movement in the past and the prediction model. Such a prediction device 20 calculates, for example, prediction values to which errors are reflected even in cases where the amount of consumed electric power varies greatly because of potential factors that are difficult to be reflected to the prediction model as input variables, such as operator proficiency that is difficult to quantify and values that are difficult to be measured. As a result, the prediction device 20 can accurately calculate the prediction value of the amount of electric power consumed by the moving object 22.

### Second Embodiment

Next, the prediction device 20 according to the second embodiment will be described. The prediction device 20 according to the second embodiment has the same functions and configurations as those of the first embodiment. Thus, the same reference symbols are assigned to elements that have the same functions and configurations as those of the first embodiment, and a detailed description of the second embodiment will not be repeated except for the differences. The same applies to each of a third embodiment and subsequent embodiments.

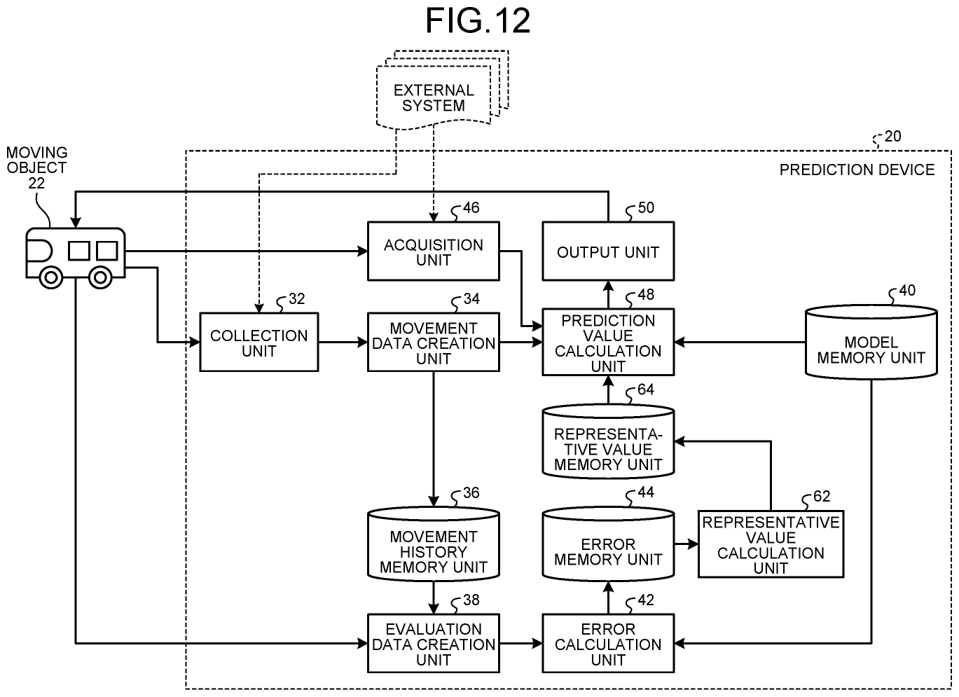

FIG. 12 is a diagram illustrating a configuration of the prediction device 20 according to the second embodiment along with the moving object 22. The prediction device 20 according to the second embodiment further includes a representative value calculation unit 62 and a representative value memory unit 64.

In a case where one or more errors with respect to one or more movements of the moving object 22 in the past are stored in the error table stored in the error memory unit 44, the representative value calculation unit 62 calculates a statistically representative value for the one or more errors. For example, the representative value calculation unit 62 calculates, as a representative value, mean, maximum, minimum, median, mode, first quartile, third quartile, variance, standard deviation, or standard error of one or more errors. The representative value calculation unit 62 may calculate, as a representative value, a root mean squared error, mean absolute error, mean squared error, root mean squared percentage error, or mean absolute percentage error. For example, the representative value calculation unit 62 calculates a representative value for each time when the error calculation unit 42 creates result data and stores the created result data in the error table.

The representative value memory unit 64 stores the representative value calculated by the representative value calculation unit 62. The representative value stored in the representative value memory unit 64 is updated to a new value for each time when a representative value is calculated by the representative value calculation unit 62.

In a case where the representative value is stored in the representative value memory unit 64, that is, an error for movement in the past is present, the prediction value calculation unit 48 according to the second embodiment acquires the representative value stored in the representative value memory unit 64 as an error. The prediction value calculation unit 48 then calculates a prediction value for the movement to be predicted by using the representative value acquired as the error and the prediction model. For example, the prediction value calculation unit 48 calculates the prediction value for the movement to be predicted by using one or more factor values, a representative value, and the second prediction model.

By contrast, in a case where the representative value is not stored in the representative value memory unit 64, that is, there is no error for the movement in the past, the prediction value calculation unit 48 according to the second embodiment calculates the prediction value for the movement to be predicted by using the prediction model, without using the representative value. For example, the prediction value calculation unit 48 calculates the prediction value for the movement to be predicted by using one or more factor values and the first prediction model.

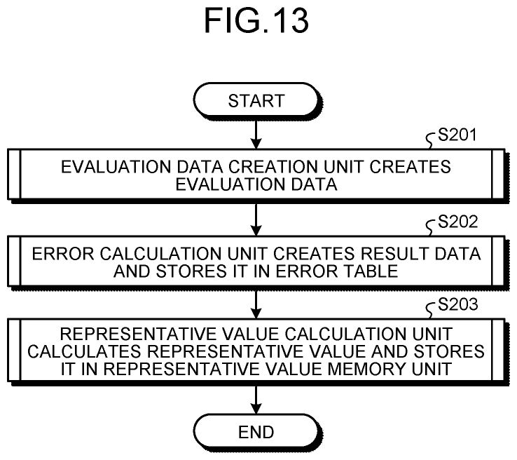

FIG. 13 is a flowchart illustrating a flow of processing executed by the prediction device 20 according to the second embodiment. In the second embodiment, in a case where movement of the moving object 22 by one unit has ended, and movement data is stored in the movement table, the prediction device 20 executes the processing illustrated in FIG. 13.

First, at S201, the evaluation data creation unit 38 acquires an actual measured value of the amount of electric power actually consumed by the moving object 22, which is due to the corresponding movement by one unit, and movement data in the corresponding movement by one unit, and creates evaluation data including the acquired actual measured value and the acquired movement data.

Next, at S202, the error calculation unit 42 calculates a prediction value of the amount of consumed electric power by using the one or more factor values extracted from the created evaluation data and the first prediction model. Furthermore, the error calculation unit 42 calculates an error between the calculated prediction value of the amount of consumed electric power and the actual measured value. The error calculation unit 42 creates one piece of result data including the calculated error and the evaluation data. The error calculation unit 42 stores the created result data in the error table stored in the error memory unit 44.

Next, at S203, the representative value calculation unit 62 calculates a representative value of one or more errors stored in the error table, in a case where the error calculation unit 42 has created result data and stored the created result data in the error table. The representative value calculation unit 62 stores the calculated representative value in the representative value memory unit 64.

As described above, the prediction device 20 according to the second embodiment calculates the prediction value of the amount of electric power consumed for the movement of the moving object 22 to be predicted by using the error for the cases of the movement in the past and the prediction model. The prediction device 20 calculates a prediction value by reflecting an error for the movements in the past. Therefore, the prediction device 20 can accurately calculate the prediction value of the amount of electric power consumed by the moving object 22.

### Third Embodiment

Next, the prediction device 20 according to a third embodiment will be described.

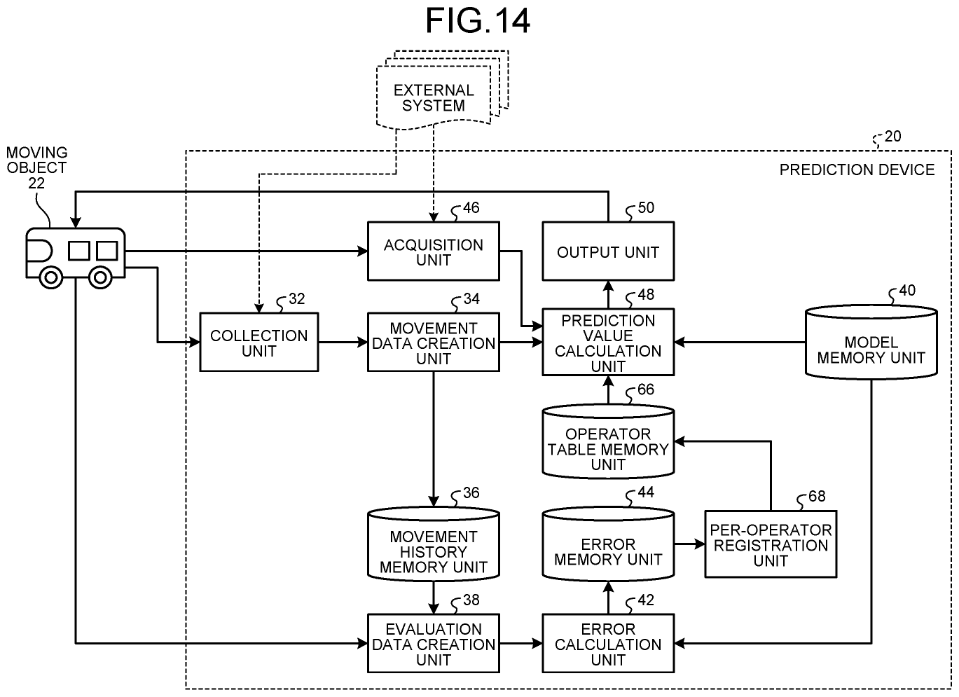

FIG. 14 is a diagram illustrating a configuration of the prediction device 20 according to the third embodiment along with the moving object 22. The prediction device 20 according to the third embodiment further includes an operator table memory unit 66 and a per-operator registration unit 68.

In the third embodiment, the collection unit 32 and the acquisition unit 46 acquire operator identification information, in a case where one or more factor values including a start position, a start time, and the like are acquired. The operator identification information is information for identifying an operator of the moving object 22. For example, the collection unit 32 and the acquisition unit 46 acquire, from the moving object 22, operator identification information that has been input into the moving object 22 by the operator. In the third embodiment, the movement data creation unit 34 creates movement data that further includes the operator identification information.

The operator table memory unit 66 stores the operator table. An error for each operator is stored in the operator table. The operator table stores, for example, an error for movement that represents the latest movement of the moving object 22 that has been operated by the operator indicated by the operator identification information. Alternatively, the operator table may store, for example, a statistical representative value of one or more errors with respect to one or more movements of the moving object 22 in the past that has been operated by the operator indicated by the operator identification information, as the error.

In a case where the error calculation unit 42 creates new result data and stores the created new result data in the error table, the per-operator registration unit 68 acquires the new result data from the error table. The per-operator registration unit 68 acquires operator identification information and an error included in the acquired new result data. The per-operator registration unit 68 then stores the acquired error in the operator table stored in the operator table memory unit 66 in association with the acquired operator identification information.

Alternatively, the per-operator registration unit 68 may calculate a statistically representative value based on the operator identification information and an error included in the acquired new result data. In this case, the per-operator registration unit 68 identifies one or more pieces of the result data including operator identification information matched with the new result data stored in the error table, and acquires one or more errors included in the identified one or more pieces of the result data. The per-operator registration unit 68 calculates, as the representative value, mean, maximum, minimum, median, mode, first quartile, third quartile, variance, standard deviation, standard error or the like of the acquired one or more errors. The per-operator registration unit 68 then stores the calculated representative value in the operator table stored in the operator table memory unit 66 in association with the acquired operator identification information, as the error.

In a case where a prediction value is calculated, the prediction value calculation unit 48 according to the third embodiment acquires the operator identification information for the movement to be predicted. In a case where an error corresponding to the acquired operator identification information is present in the operator table, that is, an error for the movement in the past in which the operator is identical is present, the prediction value calculation unit 48 according to the third embodiment acquires, from the operator table, the error for the movement in the past in which the operator is identical. The prediction value calculation unit 48 then calculates a prediction value for the movement to be predicted by using the acquired error and the prediction model. For example, the prediction value calculation unit 48 calculates the prediction value for the movement to be predicted by using one or more factor values, the acquired error, and the second prediction model.

By contrast, in a case where no error corresponding to the operator identification information is present in the operator table, that is, there is no error for the movement in the past in which the same operator is identical, the prediction value calculation unit 48 according to the third embodiment calculates the prediction value for the movement to be predicted by using the prediction model, without using the error. For example, the prediction value calculation unit 48 calculates the prediction value for the movement to be predicted by using one or more factor values and the first prediction model.

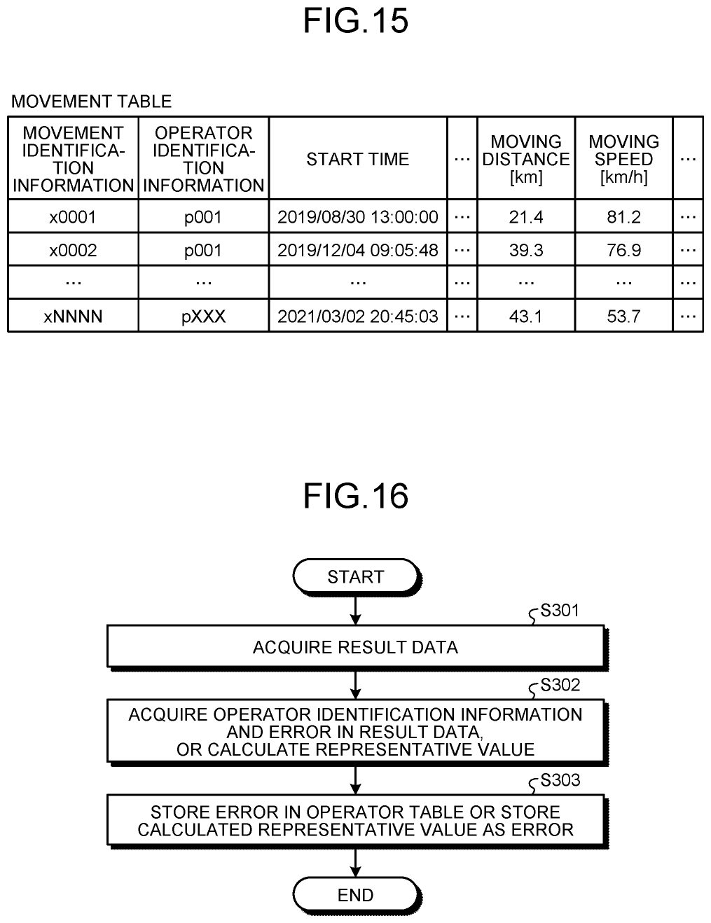

FIG. 15 is a diagram illustrating an example of the movement table according to the third embodiment. As illustrated in FIG. 15, a movement table according to the third embodiment further includes an item for storing the operator identification information as compared to the movement table according to the first embodiment. Items other than the operator identification information in the movement table according to the third embodiment are the same as those illustrated in the movement table according to the first embodiment illustrated in FIG. 2.

FIG. 16 is a flowchart illustrating a flow of update processing of errors in the operator table by the prediction device 20 according to the third embodiment. In a case where the movement of the moving object 22 ends, and the result data is stored in the error table, the prediction device 20 executes the update processing of errors according to the flow illustrated in FIG. 16.

First, at S301, in a case where the error calculation unit 42 creates new result data and stores the created new result data in the error table, the per-operator registration unit 68 acquires the new result data from the error table.

Next, at S302, the per-operator registration unit 68 acquires operator identification information and an error included in the acquired new result data. In a case of calculating a statistically representative value, the per-operator registration unit 68 identifies one or more pieces of the result data including operator identification information matched with the new result data stored in the error table, and acquires one or more errors included in the identified one or more pieces of the result data. The per-operator registration unit 68 then calculates, as the representative value, mean, maximum, minimum, median, mode, first quartile, third quartile, variance, standard deviation, standard error or the like of the acquired one or more errors.

Next, at S303, the per-operator registration unit 68 stores the acquired error or the calculated representative value in the operator table stored in the operator table memory unit 66 in association with the acquired operator identification information.

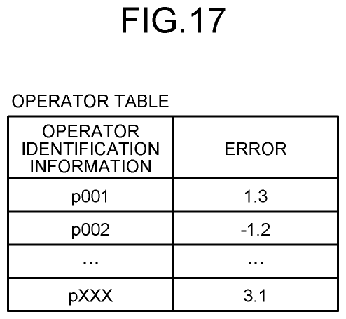

FIG. 17 is a diagram illustrating an example of the operator table. The operator table memory unit 66 stores errors for each piece of the operator identification information, for example, as illustrated in FIG. 17. As a result, the prediction value calculation unit 48 can acquire, from the operator table, the error corresponding to the operator who operates the moving object 22.

As described above, the prediction device 20 according to the third embodiment calculates the prediction value of the amount of consumed electric power by using the error for the movement in the past performed by the operator and the prediction model. Such a prediction device 20 can more accurately calculate the prediction value of the amount of electric power consumed because the prediction device 20 calculates the prediction value by reflecting a difference in operators to the prediction value.

### Fourth Embodiment

Next, the prediction device 20 according to a fourth embodiment will be described.

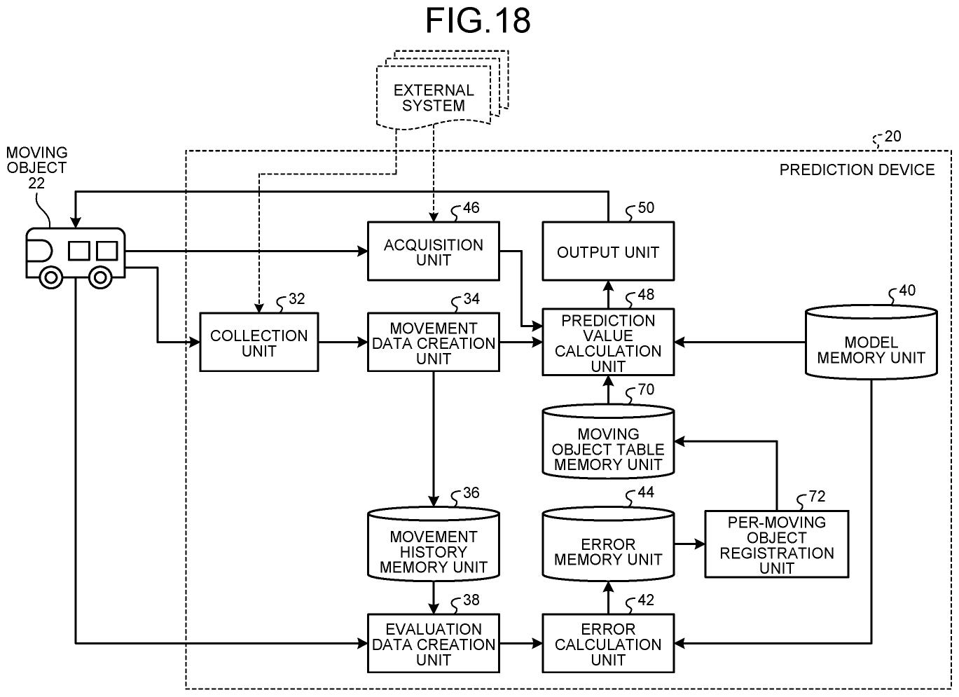

FIG. 18 is a diagram illustrating a configuration of the prediction device 20 according to the fourth embodiment along with the moving object 22. The prediction device 20 according to the fourth embodiment further includes a moving object table memory unit 70 and a per-moving object registration unit 72.

In the fourth embodiment, the collection unit 32 and the acquisition unit 46 acquire moving object identification information, in a case where one or more factor values including a start position, a start time, and the like are acquired. The moving object identification information is information for identifying the moving object 22. For example, the collection unit 32 and the acquisition unit 46 acquire, from the moving object 22, moving object identification information registered in the moving object 22 in advance.

In the fourth embodiment, the movement data creation unit 34 creates movement data that further includes the moving object identification information. A movement table according to the fourth embodiment further includes an item for storing the moving object identification information as compared to the movement table according to the first embodiment. Items other than the moving object identification information in the movement table according to the fourth embodiment are the same as those illustrated in the movement table according to the first embodiment.

The moving object table memory unit 70 stores the moving object table. An error for each moving object 22 is stored in the moving object table. The moving object table stores, for example, an error for movement that represents the latest movement of the moving object 22 indicated by the moving object identification information. Alternatively, the operator table may store, for example, a statistical representative value of one or more errors with respect to one or more movements of the moving object 22 in the past indicated by the moving object identification information, as the error.

In a case where the error calculation unit 42 creates new result data and stores the created new result data in the error table, the per-moving object registration unit 72 acquires the new result data from the error table. The per-moving object registration unit 72 acquires moving object identification information and an error included in the acquired new result data. The per-moving object registration unit 72 then stores the acquired error in the moving object table stored in the moving object table memory unit 70 in association with the acquired moving object identification information.

Alternatively, the per-moving object registration unit 72 may calculate a statistically representative value based on the moving object identification information and the error included in the acquired new result data. In this case, the per-moving object registration unit 72 identifies one or more pieces of the result data including moving object identification information matched with the new result data stored in the error table, and acquires one or more errors included in the identified one or more pieces of the result data. The per-moving object registration unit 72 calculates a statistically representative value for the acquired one or more of errors. The per-moving object registration unit 72 then stores, as the error, the calculated statistically representative value in the moving object table stored in the moving object table memory unit 70 in association with the acquired moving object identification information.

In a case where a prediction value is calculated, the prediction value calculation unit 48 according to the fourth embodiment acquires, from the moving object 22, the moving object identification information for the movement to be predicted. In a case where an error corresponding to the acquired moving object identification information is present in the moving object table, that is, an error for movement in the past is present in which the moving object 22 is identical, the prediction value calculation unit 48 according to the fourth embodiment acquires, from the moving object table, the error for movement in the past in which the moving object 22 is identical. The prediction value calculation unit 48 then calculates a prediction value for the movement to be predicted by using the acquired error and the prediction model. For example, the prediction value calculation unit 48 calculates the prediction value for the movement to be predicted by using one or more factor values, the acquired error, and the second prediction model.

By contrast, in a case where no error corresponding to the acquired moving object identification information is present in the moving object table, that is, there is no error for the movement in the past in which the moving object 22 is identical, the prediction value calculation unit 48 according to the fourth embodiment calculates the prediction value for the movement to be predicted by using the prediction model, without using the error. For example, the prediction value calculation unit 48 calculates the prediction value for the movement to be predicted by using one or more factor values and the first prediction model.

As described above, the prediction device 20 according to the fourth embodiment calculates the prediction value of the amount of consumed electric power by using the error for the movement of one and the same moving object 22 in the past and the prediction model. Such a prediction device 20 can accurately calculate the prediction value of the amount of electric power consumed because the prediction device 20 calculates the prediction value by reflecting differences in the moving object 22 to the prediction value.

### Fifth Embodiment

Next, the prediction device 20 according to a fifth embodiment will be described.

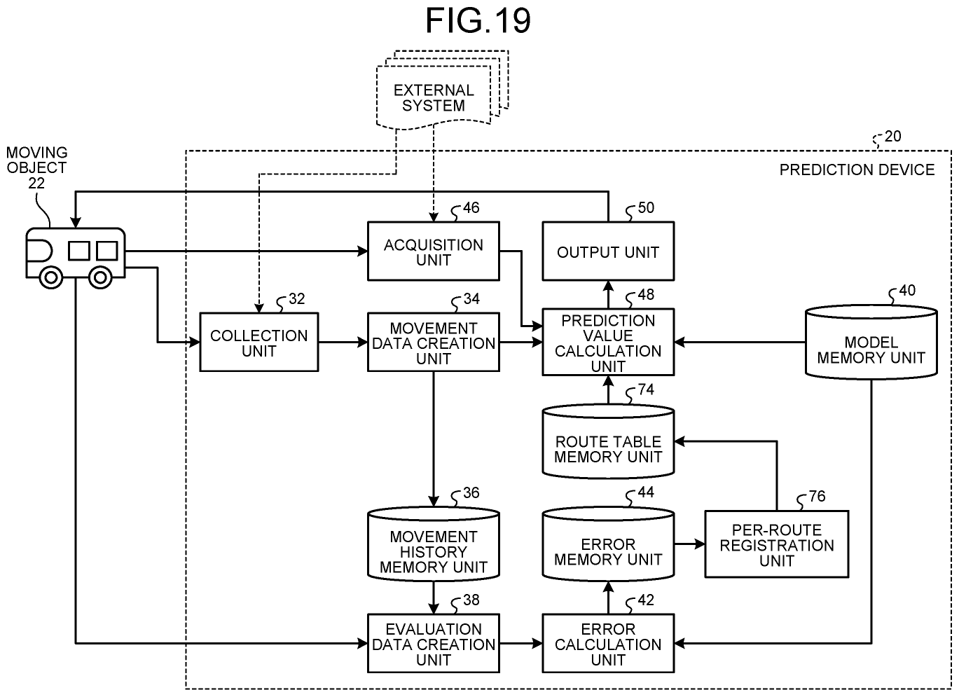

FIG. 19 is a diagram illustrating a configuration of the prediction device 20 according to the fifth embodiment along with the moving object 22. The prediction device 20 according to the fifth embodiment further includes a route table memory unit 74 and a per-route registration unit 76.

In the fifth embodiment, the collection unit 32 and the acquisition unit 46 acquire route identification information, in a case where one or more factor values including a start position, a start time, and the like are acquired. The route identification information is information for identifying a route along which the moving object 22 moves. For example, in a case where the moving object 22 is a route bus, the moving object 22 may move several different routes. The route identification information identifies which of several such routes, such as bus routes, the moving object 22 will move. For example, the collection unit 32 and the acquisition unit 46 acquire, from the moving object 22, route identification information that has been input into the moving object 22 by the operator.

In the fifth embodiment, the movement data creation unit 34 creates movement data that further includes the route identification information. A movement table according to the fifth embodiment further includes an item for storing the route identification information as compared to the movement table according to the first embodiment. Items other than the route identification information in the movement table according to the fifth embodiment are the same as those illustrated in the movement table according to the first embodiment.

The route table memory unit 74 stores the route table. An error for each route is stored in the route table. The route table stores, for example, an error for the latest movement along the route indicated by the route identification information. Alternatively, the route table may store, for example, a statistical representative value of one or more errors with respect to one or more movements along the route in the past indicated by the route identification information, as the error.

In a case where the error calculation unit 42 creates new result data and stores the created new result data in the error table, the per-route registration unit 76 acquires the new result data from the error table. The per-route registration unit 76 acquires route identification information and an error included in the acquired new result data. The per-route registration unit 76 then stores the acquired error in the route table stored in the route table memory unit 74 in association with the acquired route identification information.

Alternatively, the per-route registration unit 76 may calculate a statistically representative value based on the route identification information and the error included in the acquired new result data. In this case, the per-route registration unit 76 identifies one or more pieces of the result data including route identification information matched with the new result data stored in the error table, and acquires one or more errors included in the identified one or more pieces of the result data. The per-route registration unit 76 calculates a statistically representative value for the acquired one or more of errors. The per-route registration unit 76 then stores, as the error, the calculated representative value in the route table stored in the route table memory unit 74 in association with the acquired route identification information.

In a case where a prediction value is calculated, the prediction value calculation unit 48 according to the fifth embodiment acquires, from the moving object 22, the route identification information for the movement to be predicted. In a case where an error corresponding to the acquired route identification information is present in the route table, that is, an error for movement in the past in which a route is identical, is present, the prediction value calculation unit 48 according to the fifth embodiment acquires, from the route table, the error for movement in the past in which the route is identical. The prediction value calculation unit 48 then calculates a prediction value for the movement to be predicted by using the acquired error and the prediction model. For example, the prediction value calculation unit 48 calculates the prediction value for the movement to be predicted by using one or more factor values, the acquired error, and the second prediction model.

By contrast, in a case where no error corresponding to the acquired route identification information in the route table is present in the route table, that is, there is no error for the movement in the past in which the route is identical, the prediction value calculation unit 48 according to the fifth embodiment calculates the prediction value for the movement to be predicted by using the prediction model, without using the error. For example, the prediction value calculation unit 48 calculates the prediction value for the movement to be predicted by using one or more factor values and the first prediction model.

As described above, the prediction device 20 according to the fifth embodiment calculates the prediction value of the amount of consumed electric power by using the error for the movement in the past along one and the same route and the prediction model. Such a prediction device 20 can more accurately calculate the prediction value of the amount of electric power consumed because the prediction device 20 calculates the prediction value by reflecting differences in the route to the prediction value.

### Sixth Embodiment

Next, the prediction device 20 according to a sixth embodiment will be described.

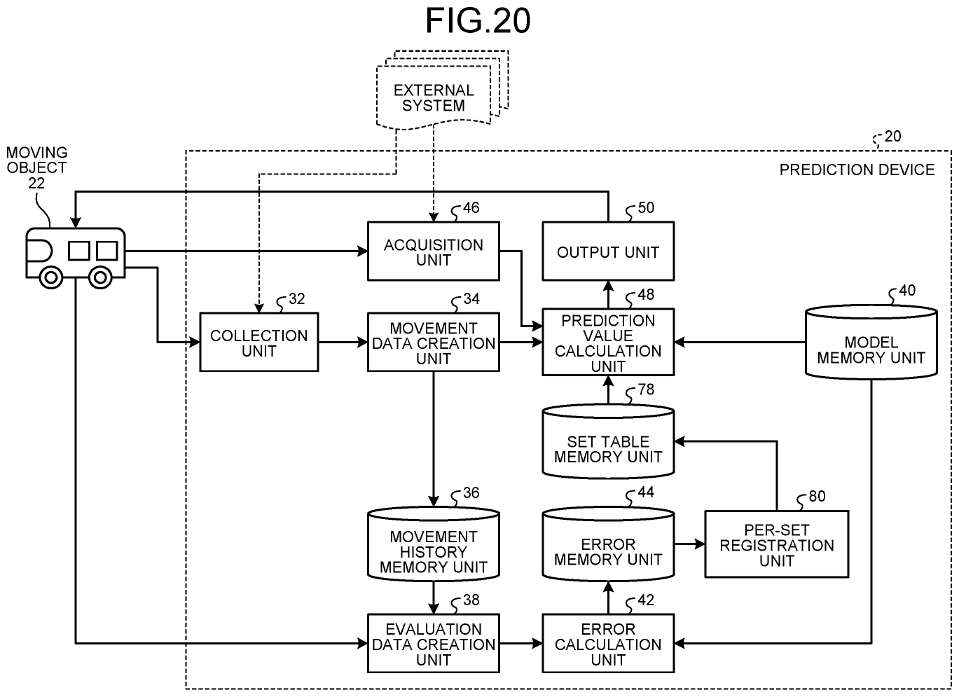

FIG. 20 is a diagram illustrating a configuration of the prediction device 20 according to the sixth embodiment along with the moving object 22. The prediction device 20 according to the sixth embodiment further includes a set table memory unit 78 and a per-set registration unit 80.

In the sixth embodiment, the collection unit 32 and the acquisition unit 46 acquire a set including predetermined two or more pieces of information out of operator identification information, moving object identification information, and route identification information, in a case where one or more factor values including a start position, a start time, and the like are acquired. The operator identification information is the same as that in the third embodiment. The moving object identification information is the same as that in the fourth embodiment. The route identification information is the same as that in the fifth embodiment.

In the sixth embodiment, the movement data creation unit 34 creates movement data that further includes a set of two or more predetermined pieces of information out of the operator identification information, the moving object identification information, and the route identification information. A movement table according to the sixth embodiment further includes an item for storing two or more predetermined pieces of information out of the operator identification information, the moving object identification information, and the route identification information as compared to the movement table according to the first embodiment. Items other than the operator identification information, the moving object identification information, and the route identification information in the movement table according to the sixth embodiment are the same as those illustrated in the movement table according to the first embodiment.

In a case where the moving object 22 has moved one or more times along the route indicated by the route identification information, a statistical representative value of one or more errors with respect to one or more movements may be stored as the error.

The set table memory unit 78 stores the set table. The set table stores an error for each set. The set table stores, for example, an error for the latest movement of a combination of the operator, the moving object 22, and the route indicated by the set identification information. Alternatively, the set table may store, for example, a statistical representative value of one or more errors with respect to one or more movements of the combination of the operator, the moving object 22, and the route indicated by the set identification information, as the error.

In a case where the error calculation unit 42 creates new result data and stores the created new result data in the error table, the per-set registration unit 80 acquires the new result data from the error table. The per-set registration unit 80 acquires a set including two or more predetermined pieces of information out of the operator identification information, the moving object identification information, and the route identification information, and an error included in the acquired new result data. The per-set registration unit 80 then stores the acquired error in the set table stored in the set table memory unit 78 in association with the acquired set.

Alternatively, the per-set registration unit 80 may calculate a statistically representative value based on the set including two or more predetermined pieces of information out of the operator identification information, the moving object identification information, and the route identification information, and the error included in the acquired new result data. In this case, the per-set registration unit 80 identifies one or more pieces of the result data having the set that includes two or more predetermined pieces of information out of the operator identification information, the moving object identification information, and the route identification information and that is matched with the new result data stored in the error table, and acquires one or more errors included in the identified one or more pieces of the result data. The per-set registration unit 80 calculates a statistically representative value for the acquired one or more of errors. The per-set registration unit 80 then stores the calculated statistically representative value in the set table stored in the set table memory unit 78 in association with the acquired set, as the error.

In a case where a prediction value is calculated, the prediction value calculation unit 48 according to the sixth embodiment acquires, from the moving object 22, the set including two or more predetermined pieces of information out of the operator identification information, the moving object identification information, and the route identification information for the movement to be predicted. In a case where an error corresponding to the acquired set is present in the set table, that is, an error for movement in the past in which a set including predetermined two or more pieces of information of the operator, the moving object 22, and the route is identical, is present, the prediction value calculation unit 48 according to the sixth embodiment acquires, from the set table, the error for movement in the past in which the set is identical. The prediction value calculation unit 48 then calculates a prediction value for the movement to be predicted by using the acquired error and the prediction model. For example, the prediction value calculation unit 48 calculates the prediction value for the movement to be predicted by using one or more factor values, the acquired error, and the second prediction model.

By contrast, in a case where no error corresponding to the acquired set is present in the set table, that is, there is no error for movement in the past in which the set including predetermined two or more pieces of information of the operator, the moving object 22, and the route, the prediction value calculation unit 48 according to the sixth embodiment calculates the prediction value for the movement to be predicted by using the prediction model, without using the error. For example, the prediction value calculation unit 48 calculates the prediction value for the movement to be predicted by using one or more factor values and the first prediction model.

As described above, the prediction device 20 according to the fifth embodiment calculates the prediction value of the amount of consumed electric power by using the error for the movement in the past with one and the same set including two or more pieces of information on the operator, the moving object 22, and the route, and the prediction model. Such a prediction device 20 can accurately calculate the prediction value of the amount of electric power consumed because the prediction device 20 calculates the prediction value by reflecting a difference in such a set to the prediction value.

In the third embodiment to the sixth embodiment, it has been described as examples that in the case where the operator, the moving object 22, or the route is one and the same, or the case where the set including two or more pieces of information on the operator, the moving object 22, and the route is one and the same, the amount of consumed electric power is predicted by using the error or representative value for the movement in the past with one and the same operator, moving object 22, route, or set. The prediction device 20 may execute, but not limited to, the same processing by using the errors or representative values for the movement in the past with the same other information. For example, the prediction device 20 may execute the same processing by using errors or representative values for the movement in the past with the same start time and end time of the movement, or the same time period during the movement.

### Seventh Embodiment

Next, the prediction device 20 according to a seventh embodiment will be described.

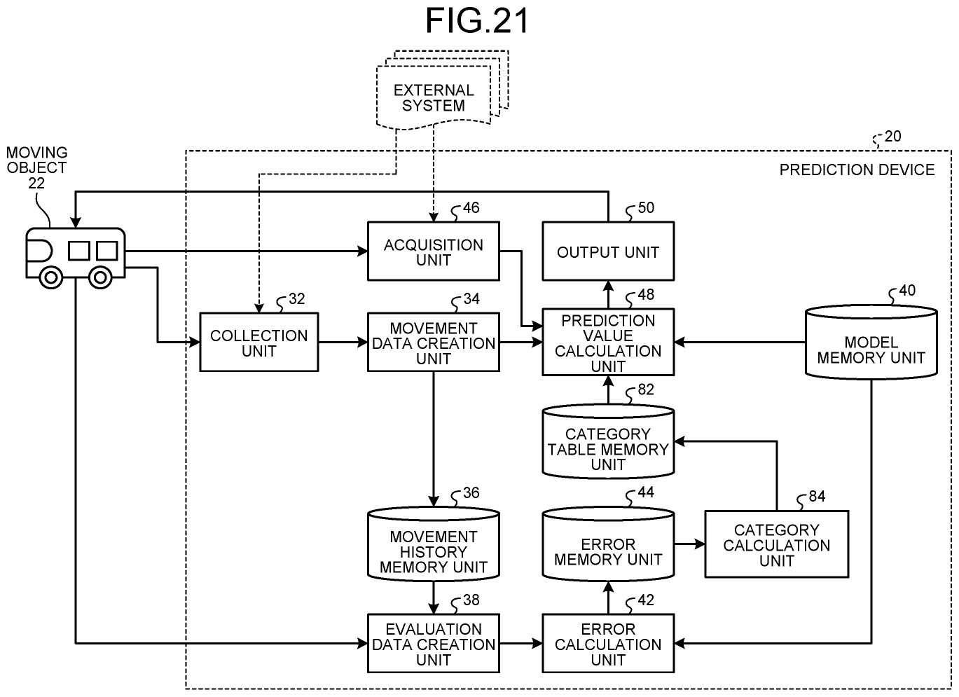

FIG. 21 is a diagram illustrating a configuration of the prediction device 20 according to the seventh embodiment along with the moving object 22. The prediction device 20 according to the seventh embodiment further includes a category table memory unit 82 and a category calculation unit 84.

The category table memory unit 82 stores a category table. The category table stores a category value and a model input value corresponding to the category value. The category value is a value indicating to which category an error belongs. The model input value corresponding to the category value is a value that is input to the prediction model, as the error. The category value may be the same value as the model input value.

In a case where the error calculation unit 42 creates new result data and stores the created new result data in the error table, the category calculation unit 84 acquires the error table from the error memory unit 44. The category calculation unit 84 calculates the movement efficiency, which represents a moving distance with respect to an actual measured value for each of the pieces of result data included in the acquired error table. The movement efficiency is called, for example, electricity cost and is represented by a unit such as km/kWh.

The category calculation unit 84 generates, based on a relationship between the movement efficiency for each of the pieces of result data and an error, an approximate curve representing the relationship between the movement efficiency for the pieces of result data and the error. The approximate curve may be a straight line. For example, the category calculation unit 84 generates correspondence points with the movement efficiency as x and the error as y with respect to each of the pieces of result data. The category calculation unit 84 then generates an approximate curve that is formed closest to a plurality of correspondence points generated. The category calculation unit 84 generates, for example, an approximate curve represented by the function y=h(x).

The category calculation unit 84 reads out, from a configuration file, efficiency setting values for classifying the movement efficiency into categories. The category calculation unit 84 inputs the read out efficiency setting values to the approximate curve to calculate a threshold value θ. For example, the category calculation unit 84 calculates the threshold value θ by inputting an efficiency setting value to x in the function y=h(x), which represents the approximate curve.

The category calculation unit 84 acquires an error for the latest movement out of the movements in the past included in the error table, and compares the calculated threshold value θ with the acquired error to determine in which category the error for the latest movement is included. The category calculation unit 84 then calculates a category value representing the determined category. Alternatively, the category calculation unit 84 may acquire a plurality of the errors for the movements in the past included in the error table and calculate a category value representing a category that includes the largest number of the errors or a category that includes a statistically representative value in the errors.

The category calculation unit 84 stores the calculated category value in a category table.

In a case where a prediction value is calculated, the prediction value calculation unit 48 according to the seventh embodiment acquires the category table from the category table memory unit 82. In a case where the category value is present in the category table, that is, an error for movement in the past is present, the prediction value calculation unit 48 according to the seventh embodiment acquires, from the category table, the model input value corresponding to the category value as an error. The prediction value calculation unit 48 then calculates a prediction value for the movement to be predicted by using the acquired model input value and the prediction model.

By contrast, in a case where no category value is present in the category table, that is, there is no error for the movement in the past, the prediction value calculation unit 48 according to the seventh embodiment calculates the prediction value for the movement to be predicted by using the prediction model, without using the model input value.

As in the third embodiment to the sixth embodiment, the category calculation unit 84 may calculate a category value for each operator, moving object 22, or route, or for each set including any two or more pieces of information on the operator, the moving object 22, and the route. In this case, as in the third embodiment to the sixth embodiment, the prediction value calculation unit 48 calculates a prediction value by using a model input value corresponding to a category value for movement in the past with one and the same operator, moving object 22, route, or set in a case where the operator, the moving object 22, or the route is one and the same, or the set including any two or more pieces of information on the operator, the moving object 22, and the route is one and the same. The prediction device 20 may execute, but not limited to, the same processing by using the category values for the movement in the past with the same other information. For example, the prediction device 20 may execute the same processing by using category values for movement in the past with the same start time and end time of movement, or the same time period during the movement.

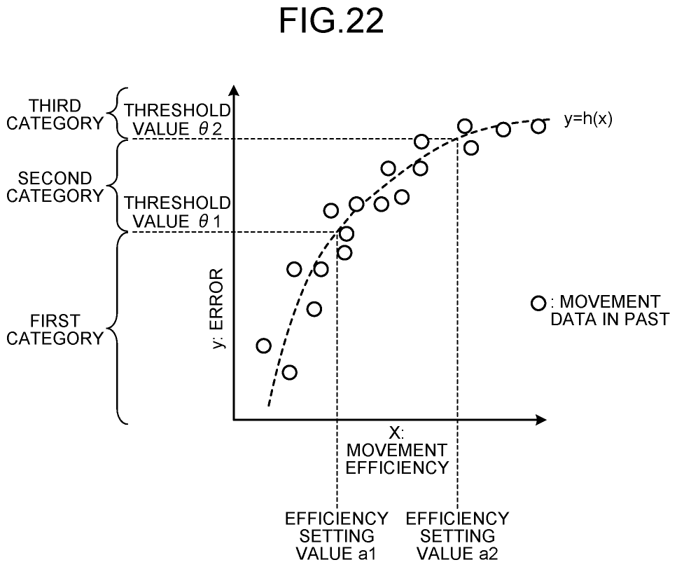

FIG. 22 is a diagram illustrating an example of an approximate curve. Errors may be closely related to movement efficiency. For example, as illustrated in FIG. 22, the approximate curve may be approximated by the function y=h(x), where x is a moving efficiency and y is an error. The function y=h(x) may be a general function, such as a linear, quadratic, exponential, logarithmic, or trigonometric function. The prediction device 20 can use such a function y=h(x) to unambiguously determine a range of threshold values for a range of each category of the movement efficiency.

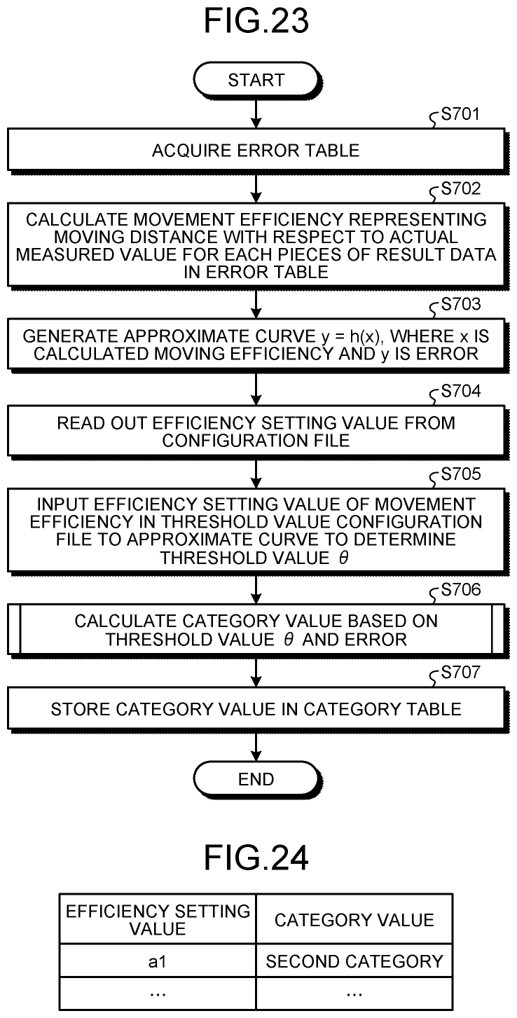

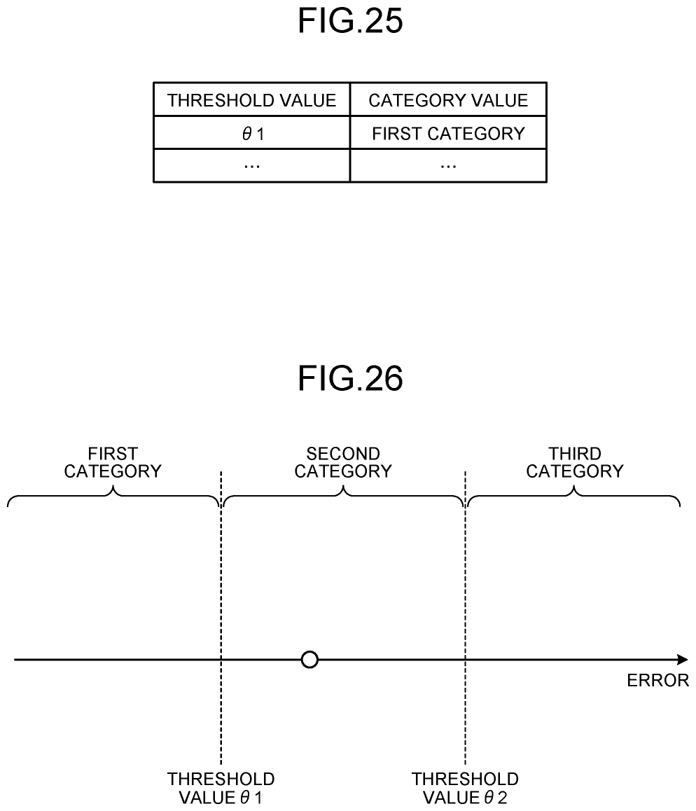

FIG. 23 is a flowchart illustrating a flow of update processing of the category value by the prediction device 20 according to the seventh embodiment. FIG. 24 is a diagram illustrating an example of a configuration file read at S704 in FIG. 23. FIG. 25 is a diagram illustrating an example of a threshold value θ determined at S705 in FIG. 23.

In a case where the movement of the moving object 22 ends, and the result data is stored in the error table, the prediction device 20 executes the update processing of errors according to the flow illustrated in FIG. 23.

First, at S701, in a case where the error calculation unit 42 creates new result data and stores the created new result data in the error table, the category calculation unit 84 acquires the error table from the error memory unit 44.

Next, at S702, the category calculation unit 84 calculates the movement efficiency, which represents a moving distance with respect to an actual measured value for each of the pieces of result data included in the acquired error table. For example, in a case where an actual measured value included in the i-th (i is an integer of equal to or greater than 1) result data is denoted by y_i, and a moving distance is denoted by x_dis\hat{ }(i), the category calculation unit 84 calculates a movement efficiency γ_i by using the following Equation.

γ_i=y_i/x_dis\hat{ }(i)

Next, at S703, the category calculation unit 84 generates, based on a relationship between the movement efficiency for each of the pieces of result data and an error, an approximate curve representing the relationship between the movement efficiency for the pieces of result data and the error. For example, the category calculation unit 84 generates correspondence points with the movement efficiency as x and the error as y with respect to each of the pieces of result data. The category calculation unit 84 then generates the function y=h(x) representing an approximate curve by fitting a coefficient of a predetermined function or the like so that the approximate curve is formed closest to a plurality of correspondence points generated.

Next, at S704, the category calculation unit 84 reads out, from a configuration file created in advance, efficiency setting values for classifying the movement efficiency into categories. The configuration file is created in advance by, for example, a designer. For example, the configuration file may be table data storing efficiency setting values and category values in columns, as illustrated in FIG. 24. For example, in a case where the configuration file classifies the movement efficiency into a first category with low efficiency or a second category with high efficiency, the configuration file stores the maximum movement efficiency of the first category as, for example, an efficiency setting value. In the case where the configuration file classifies the movement efficiency into a larger number of categories, the configuration file may store two or more efficiency setting values representing the maximum movement efficiency for each category.

Next, at S705, the category calculation unit 84 inputs the read out efficiency setting values to the approximate curve to calculate a threshold value θ. For example, the category calculation unit 84 calculates the threshold value θ by inputting an efficiency setting value to x in the function y=h(x), which represents the approximate curve. For example, the category calculation unit 84 may manage the threshold value θ by means of table data storing threshold values θ and category values in columns, as illustrated in FIG. 25. In a case where a plurality of the efficiency setting values are read out from the configuration file, the category calculation unit 84 calculates a threshold value θ corresponding to each of the efficiency setting values.

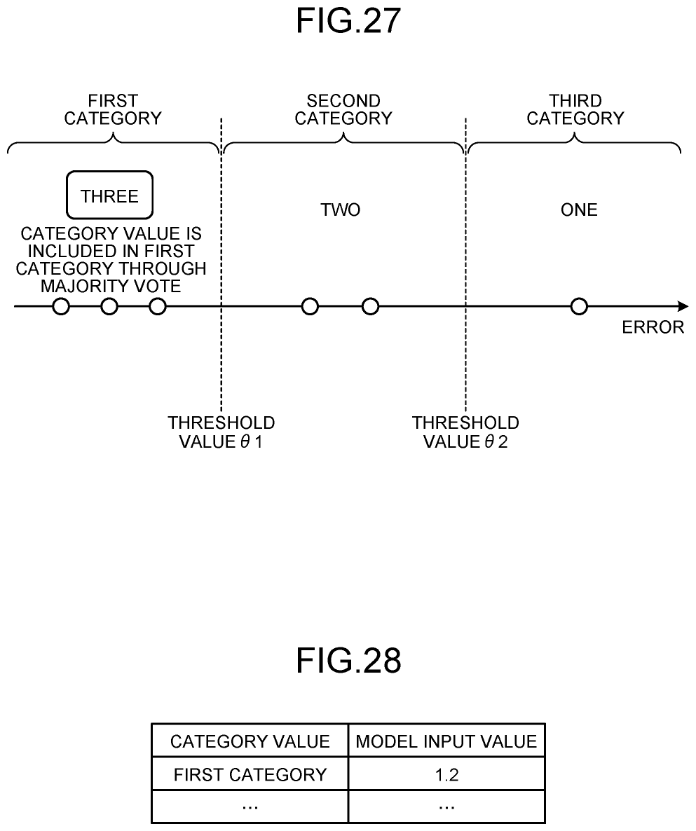

Next, at S706, the category calculation unit 84 calculates a category value based on the calculated threshold value θ and one or more errors stored in the error table. A method of calculating the category value is described later with reference to FIGS. 26 and 27.

Next, at S707, the category calculation unit 84 stores the calculated category value in the category table.

FIG. 26 is a diagram illustrating a first example of calculation processing of the category value at S706.

In a case where the error table includes the pieces of result data for the movements in the past, the category calculation unit 84 acquires, for example, an error included in the result data for the latest movement out of the movements in the past. The category calculation unit 84 may then compare the calculated one or more threshold values with the acquired error to determine in which category the error for the latest movement is included. For example, as illustrated in FIG. 26, in a case where an error is classified into any one of a first category, a second category, or a third category, a threshold value θ representing a boundary between the first category and the second category is denoted by θ1, and a threshold value representing a boundary between the second category and the third category is denoted by θ2. In this case, the category calculation unit 84 determines that the error is included in the second category, provided that the error is present between θ1 and θ2.

FIG. 27 is a diagram illustrating a second example of the calculation processing of the category value at S706.

In a case where the error table includes the pieces of result data for the movements in the past, the category calculation unit 84 acquires, for example, the errors included in the pieces of result data for the movements in the past. The category calculation unit 84 may then calculate a category value that represents the category including the largest number of the errors out of the acquired errors. For example, as illustrated in FIG. 27, in a case where an error is classified into any one of the first category, the second category, or the third category, the first category includes three errors, the second category includes two errors, and the first category includes one error. In this case, the category calculation unit 84 takes a majority vote on the number of errors to determine that the error is included in the first category.

The category calculation unit 84 may also calculate a statistically representative value in the acquired errors and calculate a category value representing the category including the calculated representative value. For example, the category calculation unit 84 may calculate the mean, median, maximum, minimum, first quartile, third quartile, or mode of errors as a representative value.

FIG. 28 is a diagram illustrating a correspondence relationship between the category values and the model input values.

The category table memory unit 82 stores a category table that stores a category value and a model input value corresponding to the category value. The model input value is a value obtained by conversion of the category value into a numerical value that can be input to the prediction model. The model input value may have the number of dummy variables corresponding to a plurality of categories, for example. In this case, each of the dummy variables represents whether it belongs to the corresponding category. For example, a dummy variable in the dummy variables corresponding to a category to which an error belongs is set to 1 and the other dummy variables are set to 0.

As described above, the prediction device 20 according to the seventh embodiment calculates a category value in which of the categories, classified by one or more threshold values, the error for movement in the past is included. The prediction device 20 according to the seventh embodiment calculates the prediction value of the amount of electric power consumed for the movement of the moving object 22 to be predicted by using the category value and the prediction model. In the case where the error is closely related to the movement efficiency, such a prediction device 20 can make a prediction value to which the error is reflected in a simple and accurate manner.

### Eighth Embodiment

Next, the prediction device 20 according to an eighth embodiment will be described.

The prediction device 20 according to the eighth embodiment has the same configuration as the first embodiment. However, the prediction device 20 according to the eighth embodiment stores, as the second prediction model, a model in which an error and one or more factor values are used as an input variable group and the amount of consumed electric power is an objective variable, as represented by the following Equation.

y_i=f(e,x_dis,x_up,x_fall, . . . ) m2:

f( ) is a function representing the prediction model. f( ) can be any model as long as it has a general form of model, such as a multiple regression model, a neural network, a deep learning, a physical model, or other forms of model. e represents an error. Parameters such as regression coefficients in the second prediction model are calculated by using general learning methods such as a least squares method, as training data including the error, factor values, and actual measured value included in the result data for the movements in the past stored in the error table, for example.

The prediction device 20 according to the eighth embodiment can improve the accuracy of the prediction value to which the error is reflected by using the prediction model with the input variable group of the error and the one or more factor values and the objective variable of the amount of consumed electric power.

### Ninth Embodiment

Next, the prediction device 20 according to a ninth embodiment will be described.

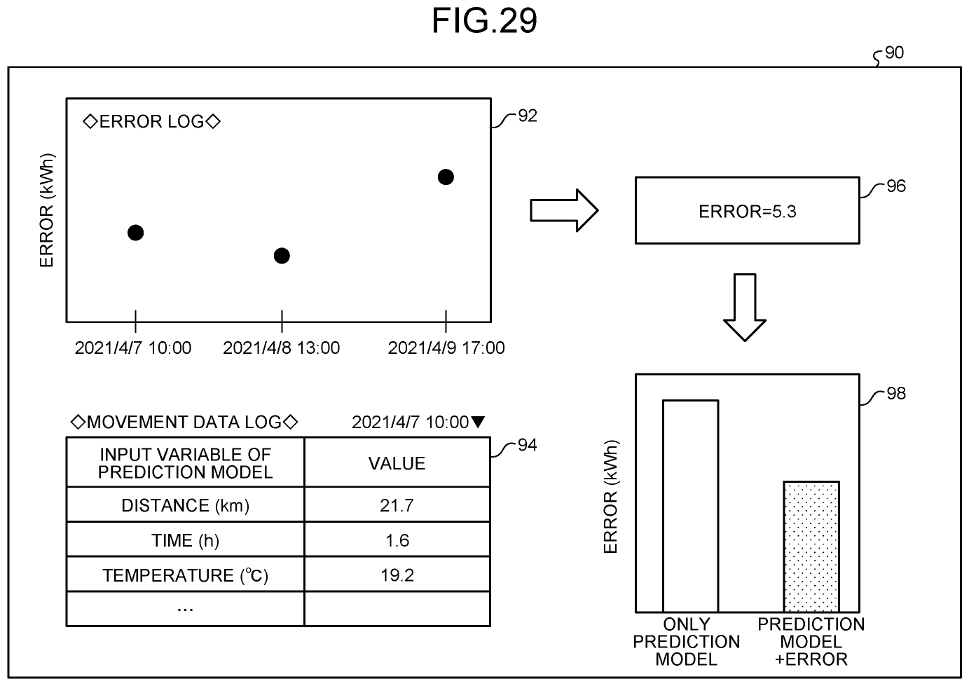

FIG. 29 is a diagram illustrating an example of an output image 90 displayed on a display device by the prediction device 20.

The output unit 50 of the prediction device 20 according to the ninth embodiment causes the display device to display the output image 90 as illustrated in FIG. 29. The output image 90 includes an error log image 92, a movement data log image 94, an error image 96, and a comparison image 98.

The error log image 92 is a graph in which errors included in the pieces of result data stored in the error table are plotted. For example, the error log image 92 is a graph illustrating date and time on the horizontal axis and error on the vertical axis. The error log image 92 is not limited to such a graph, and may be, for example, a graph illustrating other factors such as the moving time or moving distance on the horizontal axis. The prediction device 20 can illustrate the trend of errors for each factor to a manager, operator, or the like by means of displaying such an error log image 92.

The movement data log image 94 illustrates movement data related to a specified movement stored in the movement table, for example. For example, the movement data log image 94 illustrates movement data at a specified date and time.

The error image 96 is an image illustrating the error input to the prediction model. In a case where a representative value of the errors is input to the prediction model, the error image 96 may be an image illustrating the representative value.

The comparison image 98 is an image illustrating an error between a prediction value and an actual measured value, which are calculated by using the error and the prediction model, and an error between a prediction value and an actual measured value, which are calculated without using the error. The prediction device 20 can illustrate the extent to which the prediction values have been improved to the manager, operator, or the like by displaying such a comparison image 98 and inputting the error into the prediction model.

The output unit 50 provided in the prediction device 20 according to the second embodiment to the eighth embodiment may also display a similar output image 90 on a display device. The output unit 50 according to the third embodiment to the sixth embodiment may also display the output image 90 in which errors for the operator, the moving object 22, or the route, or for each set including two or more thereof are illustrated. The output unit 50 according to the sixth embodiment may also display the output image 90 that includes category values in errors.

The prediction device 20 according to the ninth embodiment as described above can illustrate the degree of improvement or trend of the prediction value to the manager, operator, or the like.

Hardware Configuration

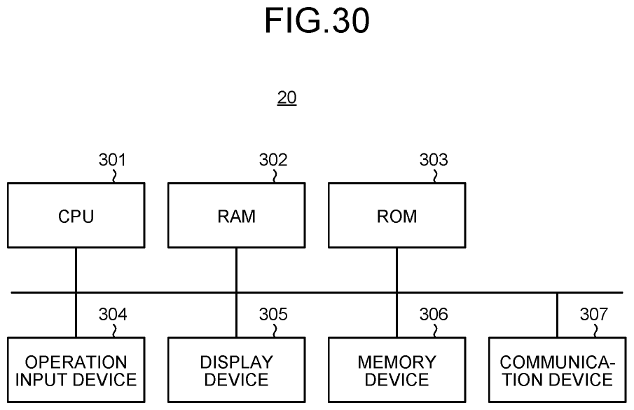

FIG. 30 is a diagram illustrating an example of a hardware configuration of the prediction device 20 according to each embodiment. The prediction device 20 is implemented by a computer with a hardware configuration as illustrated in FIG. 30, for example. The prediction device 20 is provided with a central processing unit (CPU) 301, a random access memory (RAM) 302, a read only memory (ROM) 303, an operation input device 304, a display device 305, a memory device 306, and a communication device 307. These units are connected to each other via a bus.

The CPU 301 is a processor that executes arithmetic processing, control processing, and other processing according to a computer program. The CPU 301 uses a predetermined area of the RAM 302 as a work area and executes various processes in cooperation with computer programs stored in the ROM 303, the memory device 306, and other units.

The RAM 302 is a memory such as synchronous dynamic random access memory (SDRAM). The RAM 302 serves as a work area for the CPU 301. The ROM 303 is a non-rewritable memory that stores computer programs and various pieces of information.

The operation input device 304 is an input device such as a mouse and a keyboard. The operation input device 304 accepts operation input information input by a user as an instruction signal and outputs the instruction signal to the CPU 301.

The display device 305 is a display device such as a liquid crystal display (LCD). The display device 305 displays various pieces of information based on display signals transmitted from the CPU 301.

The memory device 306 is a device that writes and reads out data on a semiconductor storage medium such as flash memory, or a magnetic or optically recordable storage medium. The memory device 306 writes and reads out data to and from the storage medium in response to controls from the CPU 301. The communication device 307 communicates with external devices via a network in response to controls from the CPU 301.

The computer program executed by a computer is composed of modules including a collection module, a movement data creation module, an evaluation data creation module, an error calculation module, an acquisition module, a prediction value calculation module, and an output module. Furthermore, the computer program may further include the following modules: a representative value calculation module, a per-operator registration module, a per-moving object registration module, a per-route registration module, and at least one of a per-route registration module or a category calculation module.

This computer program is deployed and executed on the RAM 302 by the CPU 301 (processor) to make the computer function as the collection unit 32, the movement data creation unit 34, the evaluation data creation unit 38, the error calculation unit 42, the acquisition unit 46, the prediction value calculation unit 48, and the output unit 50. The computer program may further make the computer function as at least one of the representative value calculation unit 62, the per-operator registration unit 68, the per-moving object registration unit 72, the per-route registration unit 76, the per-set registration unit 80, and the category calculation unit 84. Some or all of the collection unit 32, the movement data creation unit 34, the evaluation data creation unit 38, the error calculation unit 42, the acquisition unit 46, the prediction value calculation unit 48, the output unit 50, the representative value calculation unit 62, the per-operator registration unit 68, the per-moving object registration unit 72, the per-route registration unit 76, the per-set registration unit 80, and the category calculation unit 84 may be implemented by a hardware circuitry. The RAM 302 and the memory device 306 function as the movement history memory unit 36, the model memory unit 40, and the error memory unit 44. The RAM 302 and the memory device 306 may further function as at least one of the representative value memory unit 64, the operator table memory unit 66, the moving object table memory unit 70, the route table memory unit 74, the set table memory unit 78, and the category table memory unit 82.

The computer program to be executed by the computer is provided in a format that can be installed in the computer or as a file in an executable format in the computer, and is provided to be recorded in a computer-readable recording medium, such as CD-ROM, flexible disk, CD-R, or digital versatile disc (DVD).

This computer program may be stored in a computer connected to a network, such as the Internet, and may be configured to be provided by downloading via the network. This computer program may also be configured to be provided or distributed via a network such as the Internet. The computer program executed by the prediction device 20 may be provided with a configuration in which the computer program is pre-embedded in the ROM 303 or the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An information processing apparatus comprising
one or more hardware processors configured to
calculate a prediction value of an amount of electric power consumed for a movement to be predicted, based on
a prediction model in which the amount of electric power consumed by a moving object is an objective variable,
one or more factor values that affect the amount of electric power consumed for the movement of the moving object to be predicted, and
an error between the prediction value obtained by the prediction model and an actual measured value.

2. The apparatus according to claim 1, wherein the one or more hardware processors are further configured to:
acquires the one or more factor values with respect to the movement of the moving object to be predicted; and
output the prediction value.

3. The apparatus according to claim 2, wherein
the one or more hardware processors are configured to calculate the prediction value with respect to the movement to be predicted, by using
an error between a past prediction value that is obtained by prediction of an amount of electric power consumed for a movement of the moving object in past with the prediction model, and an actual measured value of the amount of electric power consumed for the movement in past,
the acquired one or more factor values, and
the prediction model.

4. The apparatus according to claim 3, wherein
the one or more hardware processors are configured to:
calculate the prediction value with respect to the movement to be predicted by using a first prediction model in which the one or more factor values are used as an input variable group and the amount of consumed electric power is an objective variable, in a case where the error for the movement in past is not present; and
calculate the prediction value with respect to the movement to be predicted by using a second prediction model that calculates the prediction value by adding the error to the value predicted by using the first prediction model, in a case where the error for the movement in past is present.

5. The apparatus according to claim 3, wherein
the one or more hardware processors are configured to:
calculate the prediction value with respect to the movement to be predicted by using a first prediction model in which the one or more factor values are used as an input variable group and the amount of consumed electric power is an objective variable, in a case where the error for the movement in past is not present; and
calculate the prediction value with respect to the movement to be predicted by using a second prediction model in which the error and the one or more factor values are used as an input variable group and the amount of consumed electric power is an objective variable, in a case where the error for the movement in past is present.

6. The apparatus according to claim 3, wherein
the one or more hardware processors are configured to calculate the prediction value with respect to the movement to be predicted, by using the error for a latest movement of the movement to be predicted out of a plurality of movements of the moving object in past, and the prediction model.

7. The apparatus according to claim 3, wherein
the one or more hardware processors are configured to calculate the prediction value with respect to the movement to be predicted, by using a statistically representative value in one or more errors with respect to one or more movements of the moving object in past, and the prediction model.

8. The apparatus according to claim 6, wherein
the one or more hardware processors are configured to calculate the prediction value with respect to the movement to be predicted, by using the error for the movement in past in which an operator is identical, and the prediction model in a case where the error for the movement in past in which the operator is identical, is present.

9. The apparatus according to claim 6, wherein
the one or more hardware processors are configured to calculate the prediction value with respect to the movement to be predicted, by using the error for the movement in past in which the moving object is identical, and the prediction model, in a case where the error for the movement in past in which the moving object is identical, is present.

10. The apparatus according to claim 6, wherein
the one or more hardware processors are configured to calculate the prediction value with respect to the movement to be predicted, by using the error for the movement in past in which a rout along which the moving object moves is identical, and the prediction model, in a case where the error for the movement in past in which the route is identical, is present.

11. The apparatus according to claim 6, wherein
the one or more hardware processors are configured to calculate the prediction value with respect to the movement to be predicted, by using the error for the movement in past in which a set including predetermined two or more pieces of information of an operator, the moving object, and the route along which the moving object moves is identical, and the prediction model, in a case where the error for the movement in past in which the set is identical, is present.

12. The apparatus according to claim 3, wherein the one or more hardware processors are further configured to
calculate one or more threshold values for categorizing the error, based on an approximate curve representing a relationship between a movement efficiency representing a ratio of the actual measured value to a moving distance of the moving object and the error, and calculates a category value indicating in which of categories classified by the one or more threshold values, the error for the movement in past is included, wherein
the one or more hardware processors are configured to calculate the prediction value with respect to the movement to be predicted, by using a model input value corresponding to the category value, as the error, in a case where the error for the movement in past is present.

13. The apparatus according to claim 12, wherein
the one or more hardware processors are configured to calculate the category value representing a category that includes the error for a latest movement of the movement to be predicted out of movements of the moving object in past.

14. The apparatus according to claim 12, wherein
the one or more hardware processors are configured to calculate the category value representing a category that includes a largest number of errors for movements of the moving object in past, or a category value representing a category that includes a statistically representative value in errors for movements of the moving object in past.

15. The apparatus according to claim 3, wherein
the one or more hardware processors are configured to display the error calculated by using the error and the prediction model, and the error between the prediction value calculated without using the error, and the actual measured value.

16. An information processing method of predicting an amount of electric power consumed by a moving object with an information processing apparatus, the method comprising:
calculating, by the information processing apparatus, a prediction value of the amount of electric power consumed for a movement to be predicted, based on
a prediction model in which the amount of electric power consumed by the moving object is an objective variable,
one or more factor values that affect the amount of electric power consumed for the movement of the moving object to be predicted, and
an error between the prediction value obtained by the prediction model and an actual measured value.

17. A computer program product comprising a computer-readable medium including programmed instructions, the instructions causing a computer of an information processing apparatus to function as a prediction device that predicts an amount of electric power consumed by a moving object, the instructions causing the computer to function as
a prediction value calculation unit that calculates a prediction value of the amount of electric power consumed for a movement to be predicted, based on
a prediction model in which the amount of electric power consumed by a moving object is an objective variable,
one or more factor values that affect the amount of electric power consumed for the movement of the moving object to be predicted, and
an error between the prediction value obtained by the prediction model and an actual measured value.

18. A moving object comprising the information processing apparatus according to claim 1.
